(19) United States
(12) Patent Application Publication
(10) Pub. No.: US 2025/0374679 A1
(43) Pub. Date: Dec. 4, 2025

(54) ARRAY BASE PLATE, DISPLAY PANEL AND MANUFACTURING METHOD THEREOF, AND DISPLAY APPARATUS

(71) Applicant: Tianma Advanced Display Technology Institute (Xiamen) Co., Ltd., Xiamen (CN)

(72) Inventors: Bo ZHOU, Xiamen (CN); Canyuan ZHANG, Xiamen (CN); Zufen HUANG, Xiamen (CN)

(73) Assignee: Tianma Advanced Display Technology Institute (Xiamen) Co., Ltd., Xiamen (CN)

(21) Appl. No.: 18/773,613

(22) Filed: Jul. 16, 2024

(30) Foreign Application Priority Data
May 28, 2024 (CN) 202410674730.3

(51) Int. Cl. H01L 27/12; H01L 25/075; H01L 25/16; H01L 33/62

(52) U.S. Cl. CPC H10D 86/60; H01L 25/0753; H01L 25/167; H10D 86/443; H10H 20/857

(57) ABSTRACT

The present application provides an array base plate, a display panel and a manufacturing method thereof, and a display apparatus. The array base plate includes a substrate and a plurality of conductor layers stacked on one side of the substrate, the plurality of conductor layers being provided with a conductor structure therein. The array base plate includes a first zone and a second zone, an area of an orthogonal projection of the first zone on the substrate is equal to an area of an orthogonal projection of the second zone on the substrate, and along a first direction, a distance between a center of the array base plate and the second zone is greater than a distance between the center of the array base plate and the first zone, the first direction being parallel to a plane where the substrate is located.

### CROSS-REFERENCE TO RELATED APPLICATION

This application claims priority to Chinese Patent Application No. 202410674730.3, filed on May 28, 2024, which is incorporated herein by reference in its entirety.

### TECHNICAL FIELD

The present application relates to the field of display device technology, and particularly to an array base plate, a display panel and a manufacturing method thereof, and a display apparatus.

### BACKGROUND

As the technology of micro light emitting diodes (Micro LED) continues to evolve, Micro LEDs are increasingly being used in display apparatus. Laser bonding is one of main bonding manners for Micro LEDs, and one of basic processes is to electrically connect the Micro LEDs and a base plate by aligning and pressing a temporary base plate with Micro LED chips lined up to a corresponding position of the base plate, and then heating it by laser irradiation. On this basis, how to improve bonding yield of Micro LED has become a research direction of many manufacturers.

### SUMMARY

Embodiments of the present application provide an array base plate, a display panel and a manufacturing method thereof, and a display apparatus which can improve bonding yield.

In a first aspect, the embodiments of the present application provide an array base plate including a substrate and a plurality of conductor layers stacked on one side of the substrate, the plurality of conductor layers being provided with a conductor structure therein.

The array base plate includes a first zone and a second zone, an area of an orthogonal projection of the first zone on the substrate is equal to an area of an orthogonal projection of the second zone on the substrate, and along a first direction, a distance between a center of the array base plate and the second zone is greater than a distance between the center of the array base plate and the first zone, the first direction being parallel to a plane where the substrate is located. An area of an orthogonal projection of the conductor structure within the second zone on the substrate is greater than an area of an orthogonal projection of the conductor structure within the first zone on the substrate.

In a second aspect, the embodiments of the present application provide a display panel including the array base plate of any one of the above embodiments and a plurality of light emitting elements, a part of the light emitting elements being bonded to the first zone of the array base plate and a part of the light emitting elements being bonded to the second zone of the array base plate.

In a third aspect, the embodiments of the present application provide a display apparatus including the display panel of any one of the above embodiments.

In a fourth aspect, the embodiments of the present application provide a method of manufacturing a display panel, including: providing the array base plate of any one of the above embodiments and a light emitting element; and arranging the light emitting element on one side of the array base plate, and irradiating the light emitting element and the array base plate with a movable laser source to bond and fix the light emitting element with the array base plate, the movable laser source moving in a third direction, and the first direction intersecting the third direction and both being parallel to the plane where the substrate is located.

In a fifth aspect, the embodiments of the present application provide a method of manufacturing a display panel including: providing the array base plate of any one of the above embodiments and a light emitting element; and arranging the light emitting element on one side of the array base plate, and irradiating the light emitting element and the array base plate with a fixed laser source to bond and fix the light emitting element with the array base plate, the fixed laser source being focused on the center of the array base plate.

### BRIEF DESCRIPTION OF THE DRAWINGS

In order to more clearly illustrate the technical solutions of the embodiments of the present application, the drawings to be used in the embodiments of the present application will be briefly introduced below. For those of ordinary skill in the art, other drawings can be obtained based on these drawings without inventive effort.

FIG. 1 is a schematic diagram of a correspondence between an array base plate and a line spot laser according to an embodiment of the present application;

FIG. 2 is a schematic diagram of a correspondence between another array base plate and a line spot laser according to an embodiment of the present application;

FIG. 3 is a structural schematic diagram of a conductor structure of an array base plate within a first zone according to an embodiment of the present application;

FIG. 4 is a structural schematic diagram of a conductor structure of an array base plate within a second zone according to an embodiment of the present application;

FIG. 5 is a schematic diagram of a sectional structure at A-A of FIG. 3;

FIG. 6 is a schematic diagram of a sectional structure at B-B of FIG. 4;

FIG. 7 is a schematic diagram of a sectional structure of a display panel according to an embodiment of the present application;

FIG. 8 is a structural schematic diagram of a first conductor layer of another array base plate at the first zone according to an embodiment of the present application;

FIG. 9 is a structural schematic diagram of a first conductor layer of another array base plate at the second zone according to an embodiment of the present application;

FIG. 10 is a structural schematic diagram of a first conductor layer of another array base plate at the first zone according to an embodiment of the present application;

FIG. 11 is a structural schematic diagram of a first conductor layer of another array base plate at the first zone according to an embodiment of the present application;

FIG. 12 is a structural schematic diagram of a first conductor layer of another array base plate at the first zone according to an embodiment of the present application;

FIG. 13 is a schematic diagram of a sectional structure of another array base plate at the first zone according to an embodiment of the present application;

FIG. 14 is a schematic diagram of a sectional structure of another array base plate at the second zone according to an embodiment of the present application;

FIG. 15 is a structural schematic diagram of a first conductor layer of another array base plate at the first zone according to an embodiment of the present application;

FIG. 16 is a structural schematic diagram of a first conductor layer of another array base plate at the second zone according to an embodiment of the present application;

FIG. 17 is a structural schematic diagram of a first conductor layer of another array base plate at the second zone according to an embodiment of the present application;

FIG. 18 is a structural schematic diagram of a first conductor layer of another array base plate at the second zone according to an embodiment of the present application;

FIG. 19 is a schematic diagram of a sectional structure of another array base plate at the second zone according to an embodiment of the present application;

FIG. 20 is a structural schematic diagram of a first conductor layer of another array base plate at the second zone according to an embodiment of the present application;

FIG. 21 is a structural schematic diagram of a first conductor layer of another array base plate at the second zone according to an embodiment of the present application;

FIG. 22 is a structural schematic diagram of a first conductor layer of another array base plate at the second zone according to an embodiment of the present application;

FIG. 23 is a structural schematic diagram of a first conductor layer of another array base plate at the second zone according to an embodiment of the present application;

FIG. 24 is a structural schematic diagram of a third conductor layer of another array base plate according to an embodiment of the present application;

FIG. 25 is a structural schematic diagram of a fourth conductor layer and a fifth conductor layer of another array base plate at the second zone according to an embodiment of the present application;

FIG. 26 is a structural schematic diagram of a fourth conductor layer and a fifth conductor layer of another array base plate at the second zone according to an embodiment of the present application;

FIG. 27 is a structural schematic diagram of a fourth conductor layer and a fifth conductor layer of another array base plate at the first zone according to an embodiment of the present application;

FIG. 28 is a structural schematic diagram of another array base plate according to an embodiment of the present application;

FIG. 29 is a structural schematic diagram of a conductor structure of an array base plate within a third zone according to an embodiment of the present application;

FIG. 30 is a structural schematic diagram of another array base plate according to an embodiment of the present application;

FIG. 31 is a structural schematic diagram of a conductor structure of an array base plate within a fourth zone according to an embodiment of the present application;

FIG. 32 is a structural schematic diagram of another array base plate according to an embodiment of the present application;

FIG. 33 is a structural schematic diagram of a display panel according to an embodiment of the present application;

FIG. 34 is a structural schematic diagram of another display panel according to an embodiment of the present application;

FIG. 35 is a structural schematic diagram of a display apparatus according to an embodiment of the present application;

FIG. 36 is a structural schematic diagram of another display apparatus according to an embodiment of the present application;

FIG. 37 is a flowchart of a method of manufacturing a display panel according to an embodiment of the present application;

FIG. 38 is a flowchart of another method of manufacturing a display panel according to an embodiment of the present application.

### REFERENCE SIGNS

100: array base plate; 200: display panel; 300: display apparatus;
10: substrate;
20: conductor layer; 21: conductor structure; 22: first conductor layer; 221: first conductive portion; 2211: first portion; 222: second conductive portion; 2221: second portion; 2222: third portion; 223: hollow portion; 224: first power supply structure; 225: first pad; 226: second pad; 23: second conductor layer; 24: third conductor layer; 241: hollow structure; 25: fourth conductor layer; 251: third conductive portion; 26: fifth conductor layer; 261: fourth conductive portion;
30: active layer;
40: light emitting element;
50: laser;
D1: first sub-section; D2: second sub-section; D3: main section structure; D4: branch section structure;
T: thin film transistor; T1: first electrode; T2: second electrode; T3: control terminal;
W1: first hole; W2: second hole;
A1: first zone; A2: second zone; A3: third zone; A4: fourth zone; A5: fifth zone; A6: sixth zone; A7: seventh zone;
C1: center of the array base plate; C2: center of the first zone; C3: center of the second zone; C4: center of the third zone; C5: center of the fourth zone; C6: center of the fifth zone;
X: first direction; Y: second direction; Z: thickness direction; M: third direction.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely intended to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

Laser bonding is one of main bonding manners of Micro LEDs, and one of basic processes is to align and press a temporary base plate with Micro LEDs lined up to a corresponding position of the base plate, and then heat it by laser irradiation, which allows a metal trace, a pad and a bonding layer on the base plate and a pad on the Micro LED to absorb laser energy so as to improve temperature, so that the metal of the bonding layer on the pad of the base plate is melted, thus realizing the connection between Micro LED and the base plate.

Current laser bonding manners include point spot bonding, plane spot bonding and line spot bonding. Among them, the point spot bonding has poor bonding efficiency, while the line spot bonding and the plane spot bonding have higher bonding efficiency. However, for the line spot bonding and the plane spot bonding, during laser irradiation, the bonding temperature of the center region of the spot is often greater than the bonding temperature of the edge region, which leads to the risk of poor bonding of the Micro LEDs at the edge region. Specifically, for the line spot bonding, the laser passes through the base plate along a specific scanning direction, and poor bonding of the Micro LEDs easily occurs at two edge regions in the direction that intersects the scanning direction. For the plane spot bonding, poor bonding of the Micro LEDs may likely occurs at the edge regions all around the base plate.

Further, for the Micro LEDs, the suitable bonding temperature is within a certain range. If an attempt is made to increase the bonding intensity to increase the bonding temperature, it is likely to result in the risk of bonding abnormality or damage to the base plate at the center region of the spot. Therefore, how to improve the bonding yield without damaging the base plate is a current issue that needs to be focused on.

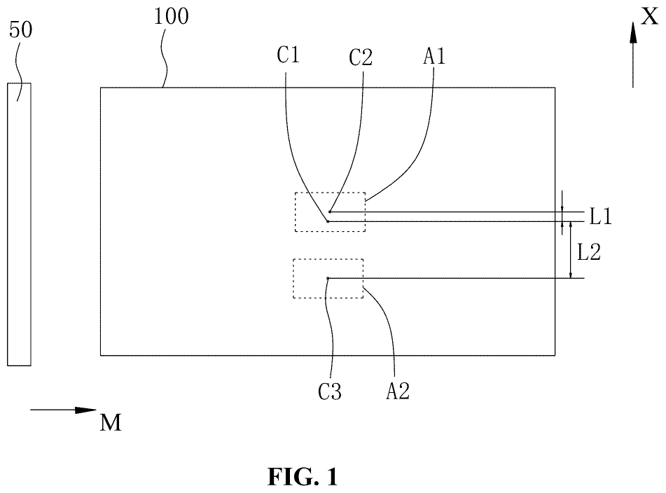

In view of above issues, in a first aspect, referring to FIG. 1 to FIG. 7, an embodiment of the present application provides an array base plate 100 which includes a substrate 10 and a plurality of conductor layers 20 stacked on one side of the substrate 10. The plurality of conductor layers 20 are provided with a conductor structure 21 therein.

The array base plate 100 includes a first zone A1 and a second zone A2. An area of an orthogonal projection of the first zone A1 on the substrate 10 is equal to an area of an orthogonal projection of the second zone A2 on the substrate 10. Along a first direction X, a distance between a center C1 of the array base plate 100 and the second zone A2 is greater than a distance between the center C1 of the array base plate 100 and the first zone A1. The first direction X is parallel to a plane where the substrate 10 is located. An area of an orthogonal projection of the conductor structure 21 within the second zone A2 on the substrate 10 is greater than an area of an orthogonal projection of the conductor structure 21 within the first zone A1 on the substrate 10.

The array base plate 100 is used to subsequently form a display panel 200. A light emitting element 40 may be fixed to the array base plate 100 by means of laser bonding and driven to emit light via the array base plate 100. The array base plate 100 is provided with a plurality of conductor and semiconductor structures therein, and the plurality of conductor and semiconductor structures 21 can together form a circuit structure to meet different needs of the display panel 200. Optionally, a part of the conductor and semiconductor structures within the array base plate 100 may be used to form a pixel circuit, and the light emitting element 40 is provided with an electrode to which the pixel circuit is electrically connected so as to realize control light emitting of the light emitting element 40.

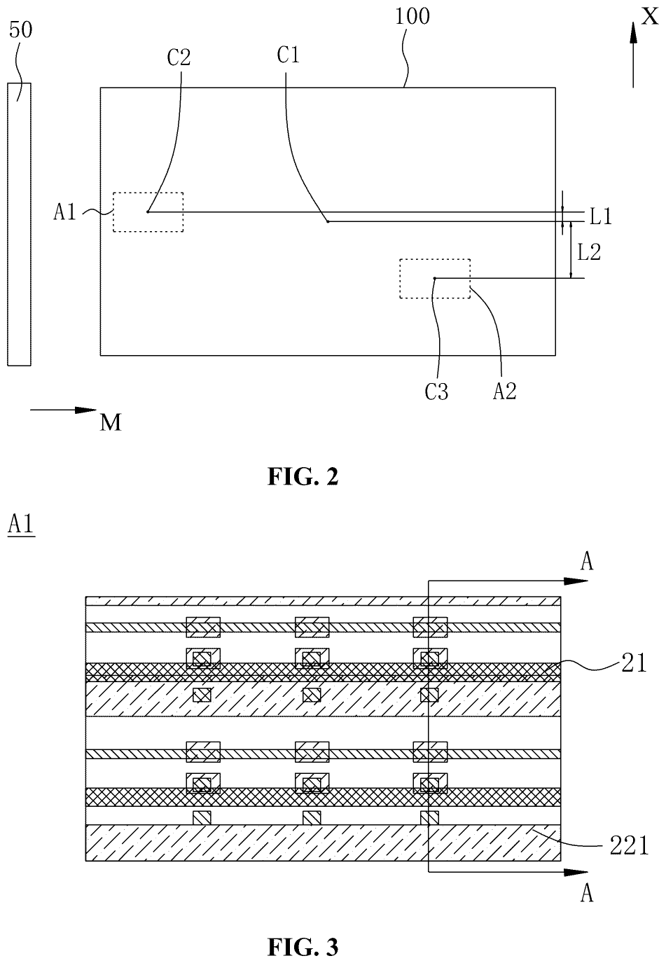

The first zone A1 and the second zone A2 are two different zones on the array base plate 100, and the area of the orthogonal projection of the first zone A1 on the substrate 10 is equal to the area of the orthogonal projection of the second zone A2 on the substrate 10. The first zone A1 and the second zone A2 both may be in a variety of shapes, for example, the orthogonal projections of the first zone A1 and the second zone A2 on the substrate 10 may be in the shape of a circle or a square or other regular or irregular shape, or the orthogonal projections of the first zone A1 and the second zone A2 on the substrate 10 may be in different shapes, which is not limited in the embodiments of the present application, as long as the areas of the orthogonal projections of the two zones on the substrate 10 are the same. FIG. 1 and FIG. 2 illustrates cases where the orthogonal projections of both the first zone A1 and the second zone A2 on the substrate 10 are square.

Along the first direction X, the distance between the center C1 of the array base plate 100 and the second zone A2 is greater than the distance between the center C1 of the array base plate 100 and the first zone A1. Specifically, the distance L2 between the center of the second zone A2 and the center C1 of the array base plate 100 in the first direction X is greater than the distance L1 between the center C2 of the first zone A1 and the center C1 of the array base plate 100 in the first direction X. The center C2 of the first zone A1 may coincide with the center C1 of the array base plate 100 in the first direction X. In this case, the distance L1 between the center C2 of the first zone A1 and the center C1 of the array base plate 100 in the first direction X is a connecting distance therebetween. Alternatively the center C2 of the first zone A1 may not coincide with the center C1 of the array base plate 100 in the first direction X. In this case, the distance L1 between the center C2 of the first zone A1 and the center C1 of the array base plate 100 in the first direction X is less than the connecting distance therebetween. The distance L2 between the center C3 of the second zone A2 and the center C1 of the array base plate 100 in the first direction X can be arranged in the same way, which will not be repeated in the embodiments of the present application. FIG. 1 illustrates a case in which the center C3 of the second zone A2 overlaps the center C1 of the array base plate 100 in the first direction X, and FIG. 2 illustrates a case in which the center C3 of the second zone A2 does not overlap the center C1 of the array base plate 100 in the first direction X.

It should be noted that, due to the shape of the array base plate 100 itself, local structural differences and other factors, the “center of the array base plate 100” mentioned here is not necessarily right the center of the array base plate 100, and there may be a certain deviation. The center of the first zone A1 and the center of the second zone A2 can be arranged in the same way. The first zone A1 and the second zone A2 may be in a variety of positional relationships with respect to the center C1 of the array base plate 100. For example, as shown in FIG. 1, an orthogonal projection of the center C1 of the array base plate 100 on the substrate 10 may be located within the orthogonal projection of the first zone A1 on the substrate 10. Or as shown in FIG. 2, the orthogonal projection of the center C1 of the array base plate 100 on the substrate 10 is located outside the orthogonal projections of the first zone A1 and the second zone A2 on the substrate 10. Further, when the orthogonal projection of the center C1 of the array base plate 100 on the substrate 10 is located outside the orthogonal projections of the first zone A1 and the second zone A2 on the substrate 10, the first zone A1 and the second zone A2 may be located on the same side or different sides of the center C1 of the array base plate 100 along the first direction X.

In addition, the first direction X is parallel to the plane where the substrate 10 is located. The first direction X has various forms depending on various bonding manners. For example, if the line spot bonding is used, the first direction X intersects the scanning direction of the laser, and further optionally, the first direction X is perpendicular to the scanning direction of the laser. If the plane spot bonding is used, the first direction X may be in any direction parallel to the plane where the substrate 10 is located. FIG. 1 and FIG. 2 illustrate cases of line spot bonding, where the scanning direction of the laser 50 is a third direction M and the first direction X is perpendicular to the third direction M.

The array base plate 100 includes a plurality of film structures that are stacked. The substrate 10 is a film for supporting in the array base plate 100, and other films are stacked on one side of the substrate 10. Herein “stacked” means that the other films are arranged in a stack manner along a thickness direction Z of the substrate 10. The thickness direction Z of the substrate 10 is usually parallel to the thickness direction Z of the other films in the array base plate 100, so for the convenience of illustration, in the embodiments of the present application, the same direction is used to represent the thickness direction Z of each film in the accompanying drawings.

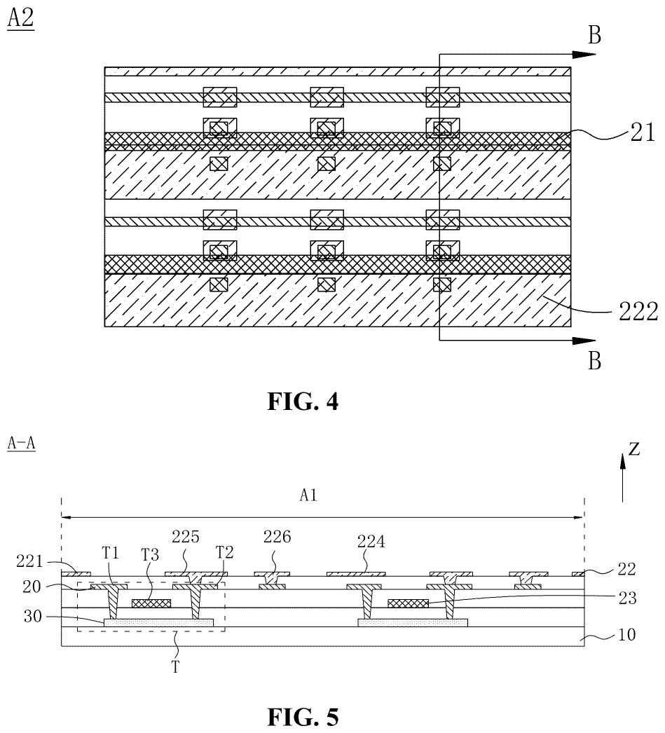

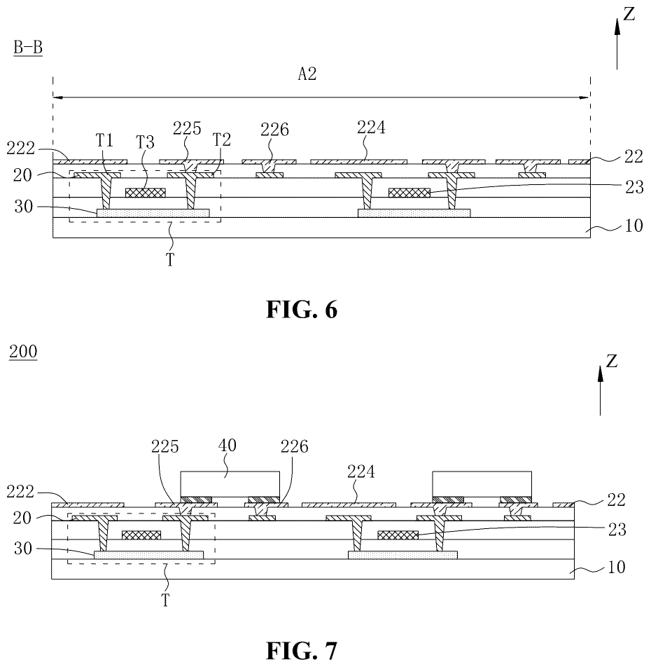

A plurality of conductor layers 20 are arranged on one side of the substrate 10. Each of the conductor layers 20 is provided with a conductor therein and an insulating layer is provided between adjacent conductor layers 20. The conductors in different conductor layers 20 may correspond to the same or different material compositions. A conductor structure 21 is provided within the plurality of conductor layers 20. Herein the plurality of conductor layers 20 may be all of the conductor layers 20 in the array base plate 100 or a part of the conductor layers 20 in the array base plate 100. Further, the conductor structure 21 herein refers to a collection of conductors in the plurality of conductor layers 20. FIG. 3 and FIG. 4 illustrate schematic diagrams of top view structures of the conductor structure 21 within the first zone A1 and the second zone A2 respectively, while FIG. 5 and FIG. 6 are schematic diagrams of sectional structures corresponding to FIG. 3 and FIG. 4. The conductors located in the different conductor layers 20 in FIG. 3 to FIG. 6 are shown using different sectional lines, and the different conductors located in the same conductor layer are shown using the same sectional lines.

The conductor structure 21 within the second zone A2 and the conductor structure 21 within the first zone A1 each corresponds to a respective area of an orthogonal projection on the substrate 10. Taking the conductor structure 21 within the second zone A2 as an example, when calculating its corresponding area of the orthogonal projection, the total area of the orthogonal projection of the part of the conductor structure 21 located within the second zone A2 on the substrate 10 is calculated. For the conductors in the conductor structure 21 that are overlapped with each other, the area of the orthogonal projection resulting from the overlapping is not double-counted when calculating the area of the orthogonal projection. The area of the orthogonal projection of the conductor structure 21 within the first zone A1 is calculated in the same way, which will not be repeated in the embodiments of the present application.

Combined with the foregoing, it can be seen that for the line spot bonding and the plane spot bonding, the bonding temperature near the region of the center C1 of the array base plate 100 tends to be higher than the bonding temperature away from the region of the center C1 of the array base plate 100. In the array base plate 100, the first zone A1 is closer to the center C1 of the array base plate 100 in the first direction X relative to the second zone A2, and thus during the bonding process, the bonding temperature at the second zone A2 tends to be lower than the bonding temperature at the first zone A1. The bonding temperature herein refers to the corresponding irradiation temperature of the laser 50 at a particular region during the bonding process, i.e., indicating the self-contained characteristics of the laser 50 when irradiating.

In view of this, in the embodiments of the present application, the structural layout and the like of the conductor structure 21 within the first zone A1 and the second zone A2 is adjusted, such that the area of the orthogonal projection of the conductor structure 21 within the second zone A2 on the substrate 10 is greater than the area of the orthogonal projection of the conductor structure 21 within the first zone A1 on the substrate 10. The area of the orthogonal projection of the conductor structure 21 within a particular region tends to be positively correlated with the ability of the array base plate 100 to absorb external heat in that region. In other words, the second zone A2 of the array base plate 100 has a stronger heat absorption ability compared to the first zone A1. On this basis, even though the bonding temperature at the second zone A2 is lower than the bonding temperature at the first zone A1, since the second zone A2 has a stronger heat absorption ability, the difference between the actual temperatures of the array base plate 100 at the first zone A1 and the second zone A2 can be reduced, so that the actual temperatures of the first zone A1 and the second zone A2 can be the same or similar, and the bonding yield and quality can thus be improved.

It is to be noted that the actual temperature mentioned herein refers to a real temperature of the array base plate 100 at a particular region during the bonding process, which is a corresponding temperature state of the array base plate 100. For the specific layout of the conductor structure 21 at the first zone A1 and the second zone A2, the embodiments of the present application are not limited. Exemplarily, the conductor size of a single conductor layer 20 within the second zone A2 may be increased such that the area of the orthogonal projection of the conductor structure 21 within the second zone A2 on the substrate 10 is greater than the area of the orthogonal projection of the conductor structure 21 within the first zone A1 on the substrate 10. Alternatively, it is also possible to increase the conductor size of a plurality of conductor layers 20 within the second zone A2, or it is also possible to reduce the size of the overlapping part of the different conductor layers 20 within the second zone A2, or it is also possible to add an additional conductor layer 20 in the array base plate 100 and increase the area of the orthogonal projection of the conductor structure 21 within the second zone A2 on the substrate 10 with the additional conductor layer 20.

In addition, for the characteristic that the bonding temperature decreases from the center region to the edge region, in some optional embodiments, in the direction from the center C2 of the first zone A1 to the center C3 of the second zone A2, the corresponding area of the orthogonal projection of the conductor structure 21 within a unit region may gradually increase, so that the layout of the conductor structure 21 may be more suitable for the trend of the bonding temperature to further improve the bonding yield and quality.

In some embodiments, as shown in FIG. 3 to FIG. 6, the plurality of conductor layers 20 includes a first conductor layer 22. The first conductor layer 22 includes a first conductive portion 221 located in the first zone A1 and a second conductive portion 222 located in the second zone A2. An area of an orthogonal projection of the second conductive portion 222 on the substrate 10 is greater than an area of an orthogonal projection of the first conductive portion 221 on the substrate 10.

The first conductor layer 22 is one of the plurality of conductor layers 20, and for the specific positional relationship of the first conductor layer 22 with respect to other conductor layers 20, the embodiments of the present application are not limited. Exemplarily, the first conductor layer 22 may be one of the plurality of conductor layers 20 that is relatively close to the substrate 10, or the first conductor layer 22 may be one of the plurality of conductor layers 20 that is relatively far from the substrate 10.

The first conductive portion 221 is a conductor in the first conductor layer 22 located at the first zone A1, and the second conductive portion 222 is a conductor in the second conductor layer 23 located at the second zone A2. The first conductive portion 221 may include only one consecutive conductor, or may also include a plurality of conductors spaced apart, which depends on the area covered by the first zone A1, a size of individual conductors in the first conductive portion 221, a size of a spacing between adjacent conductors, etc., which is not limited in the embodiments of the present application. The second conductive portion 222 is arranged in the same way. FIG. 5 and FIG. 6 illustrate cases where the first conductive portion 221 includes a plurality of conductors, and the second conductive portion 222 includes a plurality of conductors.

On this basis, at least part of the first conductive portion 221 and at least part of the second conductive portion 222 may be different components of the same consecutive conductor, or the first conductive portion 221 and the second conductive portion 222 may be arranged completely spaced apart and disconnected. And at least one of the first conductive portion 221 and the second conductive portion 222 may be used to transmit a specific signal, or at least one of the first conductive portion 221 and the second conductive portion 222 may not be provided with a potential signal therein. Further, when both the first conductive portion 221 and the second conductive portion 222 are used to transmit a specific signal, at least some of the structures of both may be electrically connected to each other, or at least some of the structures of both may be insulated from each other, which is not limited in the embodiments of the present application.

The area of the orthogonal projection of the second conductive portion 222 on the substrate 10 is greater than the area of the orthogonal projection of the first conductive portion 221 on the substrate 10. The corresponding area of the orthogonal projection of the second conductive portion 222 can be adjusted in a variety of ways. For example, it is possible to increase the extension length of single or multiple conductors in the second conductive portion 222, or it is possible to increase the width of the second conductive portion 222 at at least partial position, or it is possible to increase the number of conductors in the second conductive portion 222.

In an embodiment of the present application, the area of the orthogonal projection of the conductor structure 21 within the second zone A2 on the substrate 10 may be greater than the area of the orthogonal projection of the conductor structure 21 within the first zone A1 on the substrate 10 by changing corresponding size or layout of the second conductive portion 222 within the first conductor layer 22, i.e., by adjusting the structure of at least one of the plurality of conductor layers 20 at the second zone A2, so as to reduce the actual temperature difference between the first zone A1 and the second zone A2 of the array base plate and improve the bonding yield and quality.

It is to be noted that, depending on actual needs, it is possible to adjust parameters such as the size and the number of conductors corresponding to the conductors in the first conductor layer 22 only without adjusting the parameters such as the size and the number of conductors corresponding to the conductors in other conductor layers 20. Of course, in some other embodiments, it is also possible to simultaneously adjust the parameters such as the size and the number of conductors in the first conductor layer 22 and other conductor layers 20, which is not limited in the embodiments of the present application.

In some embodiments, as shown in FIG. 5 and FIG. 6, the array base plate includes an active layer 30, and the first conductor layer 22 is located on a side of the active layer 30 facing away from the substrate 10.

The active layer 30 is a film layer in the array base plate that includes a semiconductor structure. Exemplarily, the array base plate may include a thin film transistor T therein that includes a first electrode T1, a second electrode T2, and a control terminal T3. The control terminal T3 is used to control on or off of the first electrode T1 and second electrode T2. An orthogonal projection of the control terminal T3 on the substrate 10 overlaps the orthogonal projection of the active layer 30 on the substrate 10.

The first conductor layer 22 is located on the side of the active layer 30 facing away from the substrate 10, and the location of the first conductor layer 22 may be in a variety forms. Exemplarily, the control terminal T3 of the thin film transistor T may be located within the first conductor layer 22, or the first electrode T1 and the second electrode T2 of the thin film transistor T may be located within the first conductor layer 22, or the first conductor layer 22 may also be located on a side of the first electrode T1 facing away from the substrate 10 in the thickness direction Z, or the first conductor layer 22 may also be located between the first electrode T1 and the control terminal T3 in the thickness direction Z. FIG. 4 and FIG. 5 illustrate cases where the first conductor layer 22 is located on the side of the first electrode T1 facing away from the substrate 10 in the thickness direction Z.

Typically, in the thickness direction Z, the closer the conductor layer 20 is to the light emitting element, the stronger its ability to absorb the heat generated by the bonding process. In other words, the closer the conductor layer 20 is to the light emitting element, the greater the influence of the conductor layer 20 on the bonding effect. In view of this, in an embodiment of the present application, the first conductor layer 22 is provided on the side of the active layer 30 facing away from the substrate 10, i.e., the first conductor layer 22 can be closer to the light emitting element with respect to the active layer 30. On this basis, by adjusting the areas of the orthogonal projections corresponding to the first conductive portion 221 and the second conductive portion 222 within the first conductor layer 22, the actual temperature difference and bonding difference between the first zone A1 and the second zone A2 are reduced, thereby improving the bonding yield and quality.

In some embodiments, as shown in FIG. 5 and FIG. 6, the plurality of conductor layers 20 further includes a second conductor layer 23 located between the first conductor layer 22 and the active layer 30.

The second conductor layer 23 is one of the plurality of conductor layers 20 other than the first conductor layer 22, and the first conductor layer 22 is located on a side of the second conductor layer 23 facing away from the substrate 10. The first conductor layer 22 and the second conductor layer 23 may be in various forms. In an example where the second conductor layer 23 is a film layer where the control terminal T3 of the thin film transistor T is located, the first conductor layer 22 may be a film layer where the first electrode T1 and the second electrode T2 are located, or the first conductor layer 22 may be a film layer on the side of the first electrode facing away from the substrate 10, or the array base plate includes a storage capacitor (not shown in the figures) including one plate located within the second conductor layer 23 along with the control terminal and the other plate located within the first conductor layer 22.

The first conductor layer 22 can be closer to the light emitting element than the second conductor layer 23. Further, the first conductor layer 22 has a greater influence on the bonding effect of the light emitting element than the second conductor layer 23. On this basis, in an embodiment of the present application, the bonding yield and quality is improved by adjusting the areas of the orthogonal projections of the first conductive portion 221 and the second conductive portion 222 within the first conductor layer 22 and therefore further reducing the actual temperatures difference and bonding difference between the first zone A1 and the second zone A2.

It is to be noted that for the second conductor layer 23, depending on actual needs, an area of an orthogonal projection of the second conductor layer 23 at the first zone A1 may be greater than, less than or equal to an area of an orthogonal projection of the second conductor layer 23 at the second zone A2. That is, in an embodiment of the present application, in order to improve the bonding yield at the second zone A2, at least the conductors in the first conductor layer 22 need to be adjusted, while the conductors in the second conductor layer 23 may be adjusted selectively corresponding to the first zone A1 and the second zone A2, or it may be unchanged.

In some embodiments, both the first conductive portion 221 and the second conductive portion 222 transmit a power signal.

The power signal is a constant voltage, and may include a PVDD signal and a PVEE signal. Exemplarily, the array base plate 100 may also include a plurality of pixel circuits that are circuit structures in the array base plate 100 for controlling the light emitting element 40. The light emitting element 40 is provided with two electrodes. The PVDD signal may be electrically connected to the pixel circuit that is electrically connected to one of the electrodes of the light emitting element 40, and the PVEE signal is electrically connected to another electrode of the light emitting element 40.

On this basis, the first conductive portion 221 and the second conductive portion 222 may both be used to transmit the PVDD signal, or the first conductive portion 221 and the second conductive portion 222 may both be used to transmit the PVEE signal, or one of the first conductive portion 221 and the second conductive portion 222 may be used to transmit the PVDD signal and the other may be used to transmit the PVEE signal. Or at least one of the first conductive portion 221 and the second conductive portion 222 may also be partially used to transmit the PVDD signal and partially used to transmit the PVEE signal. In other words, the type of power signal to be transmitted by the first conductive portion 221 and the second conductive portion 222 depends mainly on factors such as size, shape, and position of the first zone A1 and the second zone A2, which is not limited in the embodiments of the present application. FIG. 5 and FIG. 6 illustrate cases where both the first conductive portion 221 and the second conductive portion 222 are partially used to transmit the PVDD signal and partially used to transmit the PVEE signal.

In an embodiment of the present application, the first conductive portion 221 and the second conductive portion 222 both transmit the power signal. In order to meet the transmission of the power signal, the first conductive portion 221 and the second conductive portion 222 need to be set in a position closer to the light emitting element 40. On this basis, by increasing the size of the second conductive portion 222, the area of the orthogonal projection of the second conductive portion 222 on the substrate 10 is greater than the area of the orthogonal projection of the first conductive portion 221 on the substrate 10, so as to facilitate to further increase the actual temperature of the array base plate at the second zone A2, thereby improving the bonding yield and quality at the second zone A2.

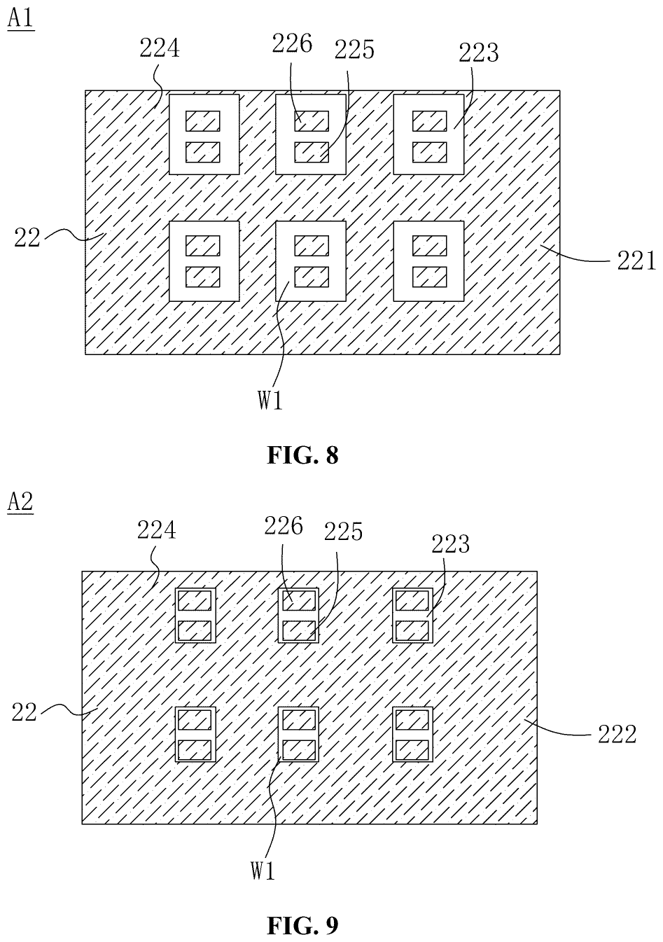

In some embodiments, referring to FIG. 8 and FIG. 9, the first conductor layer 22 is a plane structure.

It is to be noted that the plane structure herein means that the orthogonal projection of the first conductor layer 22 on the substrate is capable of covering a large portion of the substrate. Exemplarily, the orthogonal projection of the first conductor layer 22 on the substrate covers 50% or more of the substrate.

In an embodiment of the present application, the first conductor layer 22 is a plane structure. On this basis, the structure of the first conductor layer 22 can be designed differently in the first zone A1 and the second zone A2, so as to enable the area of the orthogonal projection of the second conductive portion 222 on the substrate to be greater than the area of the orthogonal projection of the first conductive portion 221 on the substrate, thereby improving the bonding yield and quality.

It is to be noted that the specific manner in which the first conductor layer 22 is differentially designed in the first zone A1 and the second zone A2 is not limited in the embodiments of the present application. Exemplarily, in an example where the first conductive portion 221 and the second conductive portion 222 both transmit the power signal, in order to satisfy the need for transmission of the PVDD signal and the PVEE signal in the first conductor layer 22, the first conductor layer 22 includes at least a plurality of conductors insulated from each other. On this basis, the spacing size of the two kinds of conductors can be adjusted with respect to the first zone A1 and the second zone A2, to enable the area of the orthogonal projection of the second conductive portion 222 on the substrate 10 to be greater than the area of the orthogonal projection of the first conductive portion 221 on the substrate 10. Or it is also possible to enable the area of the orthogonal projection of the second conductive portion 222 on the substrate 10 to be greater than the area of the orthogonal projection of the first conductive portion 221 on the substrate 10 by arranging a hole structure on at least one of the two kinds of conductors.

In some embodiments, as shown in FIG. 8 and FIG. 9, the first conductor layer 22 is provided with hollow portions 223 which are at least partially located in the first zone A1.

The hollow portions 223 are hollow structures formed by patterning of the first conductor layer 22. The hollow portions 223 are arranged through the first conductor layer 22 along the thickness direction. The hollow portions 223 are in various forms. In an example where the first conductor layer 22 includes a plurality of conductors insulated from each other, at least part of the hollow portions 223 may be a gap space arranged between the two conductors, or at least part of the hollow portions 223 may be a hole structure arranged on either of the two conductors.

The position of the hollow portions 223 may be in various forms. For example, the hollow portions 223 are at least partially located in the first zone A1 and there is no hollow portions 223 in the second zone A2, i.e., the first conductor layer 22 is in a complete consecutive structure at the first zone A1. Alternatively, the hollow portions 223 may be partially located in the first zone A1 and partially located in the second zone A2, as long as it is satisfied that the hollow portions 223 are at least partially located in the first zone A1. FIG. 8 and FIG. 9 illustrate that the hollow portion 223 are partially located in the first zone A1 and partially located in the second zone A2, and a size of an orthogonal projection of the hollow portions 223 in the first zone A1 is greater than a size of an orthogonal projection of the hollow portions 223 in the second zone A2.

In an embodiment of the present application, the hollow portions 223 are at least partially located in the first zone A1. The adjustment of the area of the orthogonal projection of at least one of the first conductive portion 221 and the second conductive portion 222 on the substrate is achieved by adjusting the total area of the orthogonal projection of all the hollow portions 223 on the substrate in at least one of the first zone A1 and the second zone A2, so that the area of the orthogonal projection of the second conductive portion 222 on the substrate is greater than the area of the orthogonal projection of the first conductive portion 221 on the substrate, which is highly flexible and practical.

In some embodiments, referring to FIG. 8 to FIG. 10, the number of hollow portions 223 in the first zone A1 is greater than the number of hollow portions 223 in the second zone A2; and/or the area of the orthogonal projection of the hollow portions 223 in the first zone A1 on the substrate is greater than the area of the orthogonal projection of the hollow portions 223 in the second zone A2 on the substrate.

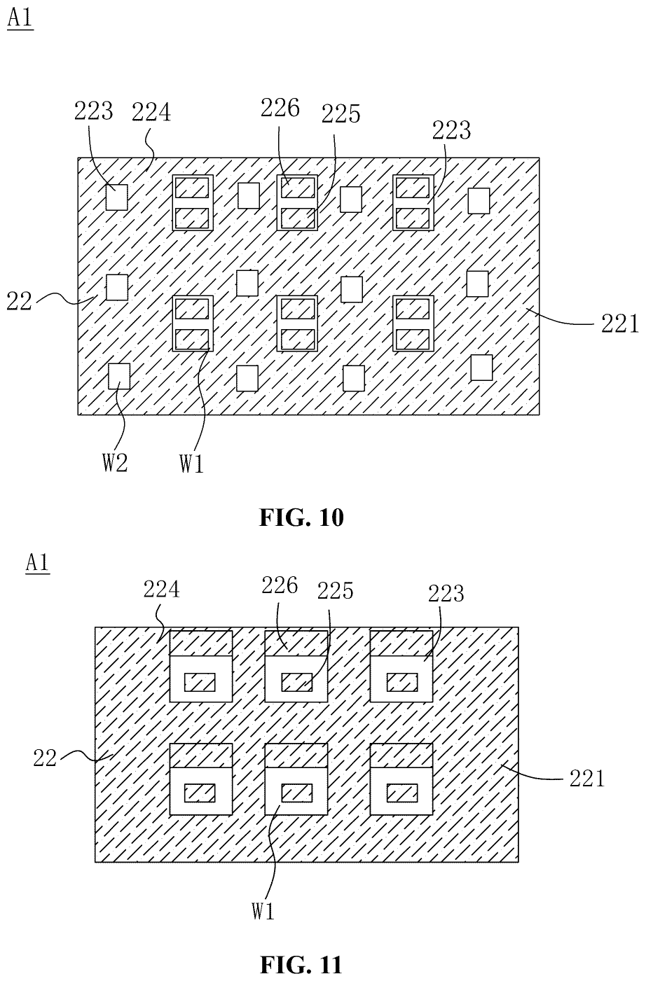

Depending on various actual needs, the number of hollow portions 223 may be a plurality, and at least some of the plurality of hollow portions 223 will be provided within the first zone A1. On this basis, as shown in FIG. 9 and FIG. 10, by adjusting the number of hollow portions 223 in the first zone A1 to be greater than the number of hollow portions 223 in the second zone A2, the total area of the orthogonal projection of all hollowed portions 223 in the first zone A1 on the substrate can be greater than the total area of the orthogonal projection of all hollowed portions 223 in the second zone A2 on the substrate. In this way, it can be realized that the area of the orthogonal projection of the second conductive portion 222 on the substrate is greater than the area of the orthogonal projection of the first conductive portion 221 on the substrate.

It is to be noted that the second zone A2 may or may not be provided with the hollow portions 223. When the second zone A2 is not provided with the hollow portions 223, the number of the hollow portions 223 in the second zone A2 is zero.

As shown in FIG. 8 and FIG. 9, in addition to adjusting the number of hollow sections 223 in different regions, the size of individual hollow sections 223 in different regions can also be adjusted, so that the area of the orthogonal projection of individual hollow sections 223 in the first zone A1 on the substrate is greater than the area of the orthogonal projection of individual hollow sections 223 in the second zone A2 on the substrate. In this way, it also can be realized that the area of the orthogonal projection of the second conductive portion 222 on the substrate is greater than the area of the orthogonal projection of the first conductive portion 221 on the substrate.

Of course, in some other embodiments, while adjusting the number of hollow sections 223 in the first zone A1 to be greater than the number of hollow sections 223 in the second zone A2, the area of the orthogonal projection of the hollow sections 223 in the first zone A1 on the substrate can be arranged to be greater than the area of the orthogonal projection of the hollow sections 223 in the second zone A2 on the substrate, which facilitates to further increase the difference between the areas of the orthogonal projections of the second conductive portion 222 and the first conductive portion 221.

In an embodiment of the present application, the number of hollow portions 223 in different regions can be selectively adjusted, or the size of individual hollow portions 223 in different regions can be selectively adjusted, so as to realize that the area of the orthogonal projection of the second conductive portion 222 on the substrate is greater than the area of the orthogonal projection of the first conductive portion 221 on the substrate, thereby increasing the bonding yield and quality, which is highly flexible and practical.

In some embodiments, the first conductor layer 22 includes a first power supply structure 224 used to provide a first supply voltage.

The first power supply structure 224 is a conductor for providing the first supply voltage. Optionally, as shown in FIG. 8 to FIG. 10, the first power supply structure 224 is used to transmit the PVDD signal. Or referring to FIG. 11, the first power supply structure 224 may also be used to transmit the PVEE signal. Further, the first power supply structure 224 is a plane structure, so that the first conductive portion 221 may include a part of the first power supply structure 224, and similarly the second conductive portion 222 may include a part of the first power supply structure 224.

On this basis, in an embodiments of the present application, by arranging the hollow portions 223 in the first power supply structure 224 and adjusting the number, the size or the like of hollow portions 223 in different regions, an area of an orthogonal projection of the first power supply structure 224 in the second zone A2 can be greater than an area of an orthogonal projection of the first power supply structure 224 in the first zone A1, so as to enable the area of the orthogonal projection of the second conductive portion 222 on the substrate to be greater than the area of the orthogonal projection of the first conductive portion 221 on the substrate, thereby improving the bonding yield and quality.

In addition, since the first power supply structure 224 is a plane structure, the overall size of the first power supply structure 224 can be increased, so as to reduce the resistance of the first power supply structure 224, thereby reducing voltage drop when transmitting the signal on the first power supply structure 224, reducing the loss of the power consumption of the first power supply structure 224, improving the problem of uneven display, and improving the display effect.

In some embodiments, as shown in FIG. 7 to FIG. 11, the first conductor layer 22 further includes a first pad 225 which is insulated from the first power supply structure 224.

The first pad 225 may be a structure in the array base plate 100 for bonding connection with the light emitting element 40. Optionally, the light emitting element 40 includes two electrodes, and the first conductor layer 22 further includes a second pad 226. As shown in FIG. 8 to FIG. 10, the first power supply structure 224 is used to transmit the PVDD signal, both the first pad 225 and the second pad 226 are insulated from the first power supply structure 224, and the first pad 225 and the second pad 226 are bonded and fixed to the two electrodes of the light emitting element 40 respectively. Alternatively, as shown in FIG. 11, the first power supply structure 224 is used to transmit the PVEE signal, the first power supply structure 224 is only insulated from the first pad 225 but electrically connected with the second pad 226. Optionally, the second pad 226 and the first power supply structure 224 may be an integral structure.

Further, in combination with the foregoing, it can be seen that the first power supply structure 224 is a plane structure. On this basis, in order to meet the need for insulation between the first power supply structure 224 and the first pad 225, the first power supply structure 224 needs to be provided with a first hole W1 for accommodating the first pad 225, and the first pad 225 needs to be spaced apart from the first power supply structure 224. The second pad 226 may be located within the first hole W1 together with the first pad 225, or the second pad 226 may be located outside the first hole W1, which is not limited in the embodiments of the present application. FIG. 8 to FIG. 10 illustrate cases where both the first pad 225 and the second pad 226 are located within the first hole W1, and FIG. 11 illustrates the case where only the first pad 225 is located within the first hole W1.

In this design, the gap space between the first pad 225 and the first power supply structure 224 is the hollow portion 223. On this basis, it is possible to increase the size of the gap between the first pad 225 and the first power supply structure 224 in the first zone A1, so as to increase the size of individual hollow portion 223 in the first zone A1, thereby enabling the area of the orthogonal projection of the second conductive portion 222 on the substrate 10 to be greater than the area of the orthogonal projection of the first conductive portion 221 on the substrate 10.

Alternatively, as shown in FIG. 10, a second hole W2 can be added additionally in the first power supply structure 224 at a location in the first zone A1 other than the location of the first pad 225, and the second hole W2 is also a hollow portion 223. In this design, the total area of the orthogonal projection of all the hollow portions 223 in the first zone A1 can be increased so that the area of the orthogonal projection of the second conductive portion 222 on the substrate 10 can also be greater than the area of the orthogonal projection of the first conductive portion 221 on the substrate 10.

It is to be noted that, for the technical solution of adding the additional second hole W2 in the first power supply structure 224 at a location other than the location of the first pad 225, in addition to the first zone A1 being provided with the second hole W2, the second zone A2 can also be provided with the second hole W2. On this basis, control of corresponding areas of the orthogonal projections of the first conductive portion 221 and the second conductive portion 222 can be realized by adjusting the number of the second holes W2 or the size of individual second holes W2 in the first zone A1 and the second zone A2.

In addition, since the adjacent insulating layers on both sides of the first power supply structure 224 in the thickness direction Z are usually made of an inorganic material, the provision of the hole structure can improve the adhesion between the first power supply structure 224 and its adjacent insulating layers, reduce the risk of peeling off of the first power supply structure 224 with respect to the adjacent film layers, and improve reliability.

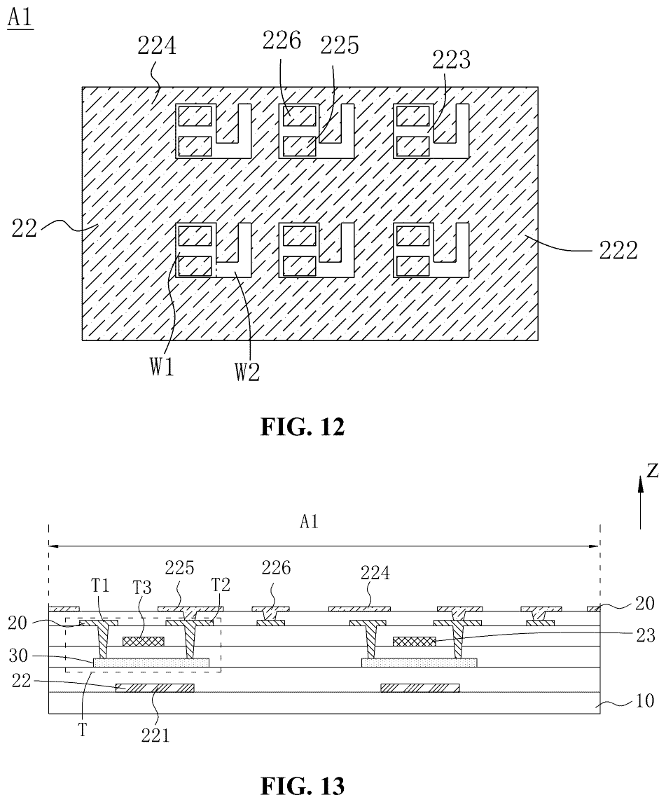

In addition to the structure shown in FIG. 8 to FIG. 11, the first power supply structure 224 may be in other structural forms. For example, referring to FIG. 12, the first power supply structure 224 is also a plane structure, but different from FIG. 10, the second hole W2 formed on the first power supply structure 224 in FIG. 12 is connected to the first hole W1 for accommodating the first pad 225. The first hold W1 and the second hole W2 may be in a variety of shapes in addition to those shown in the figures, which is not limited in the embodiments of the present application.

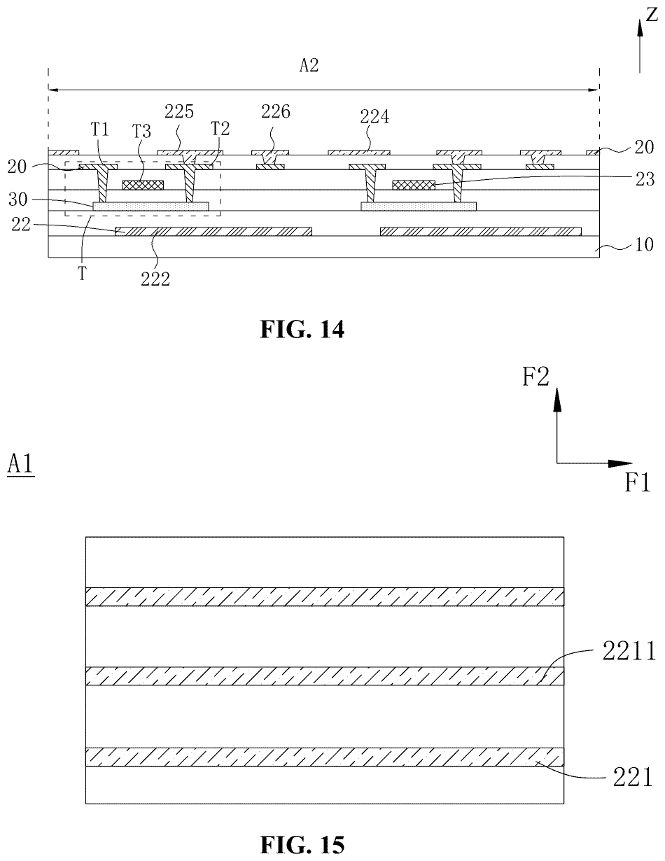

In some embodiments, referring to FIG. 13 and FIG. 14, the array base plate 100 further includes an active layer 30, with the first conductor layer 22 located on a side of the active layer 30 facing the substrate 10.

As can be seen in conjunction with the foregoing embodiments, the first conductor layer 22 may be located either on the side of the active layer 30 facing away from the substrate 10 or on the side of the active layer 30 facing the substrate 10. In other words, in order to improve the bonding yield, the conductors in the conductor layer 20 on the side of the active layer 30 facing away from the substrate 10 may be adjusted, or the conductors in the conductor layer 20 on the side of the active layer 30 facing the substrate 10 may also be adjusted. Of course in some other embodiments, both the conductors in the conductor layer 20 on the side of the active layer 30 facing the substrate 10 and the conductors in the conductor layer 20 on the side of the active layer 30 facing away from the substrate 10 may be adjusted. The adjustment is highly flexible and can meet the needs of different situations.

It is to be noted that the first conductive portion 221 in the first conductor layer 22 may or may not be arranged in correspondence with the active layer 30, i.e., the orthogonal projection of the first conductive portion 221 on the substrate 10 may or may not overlap the orthogonal projection of the active layer 30 on the substrate 10. The relationship between the second conductive portion 222 and the active layer 30 can be arranged in the same way.

In addition, since the conductors in the conductor layer 20 on the side of the active layer 30 facing the substrate 10 are usually not used to realize specific functions such as light emitting, touch control and the like, even if some of the conductors in this conductor layer 20 are eliminated, normal use of the subsequently formed display panel will not be affected. In view of this, in some other optional embodiments, a conductor layer 20 is provided on the side of the active layer 30 facing the substrate 10, and an orthogonal projection of a conductor in the conductor layer 20 on the substrate 10 is located within the orthogonal projection of the second zone A2 on the substrate 10 and outside the orthogonal projection of the first zone A1 on the substrate 10. In other words, based on the above-described embodiments, the first conductive portion 221 can be canceled so that the area of the orthogonal projection of the conductor structure 21 within the second zone A2 is greater than the area of the orthogonal projection of the conductor structure 21 within the first zone A1.

In some embodiments, as shown in FIG. 13 and FIG. 14, the orthogonal projections of both the first conductive portion 221 and the second conductive portion 222 on the substrate 10 overlap the orthogonal projection of the active layer 30 on the substrate 10.

The array base plate is usually provided with a thin film transistor T. A part of the structure in the thin film transistor T may be located in the active layer 30, and the first conductor layer 22 is located on the side of the active layer 30 facing the substrate 10. On this basis, the orthogonal projections of both the first conductive portion 221 and the second conductive portion 222 on the substrate 10 overlap the orthogonal projection of the active layer 30 on the substrate 10. In this way, the first conductive portion 221 and the second conductive portion 222 can play a role in absorbing a part of reflected light within the display panel, thereby reducing the amount of light reflected into the active layer 30 and improving operational reliability of the thin film transistor.

It should be noted that, according to various actual needs, at least one of the first conductive portion 221 and the second conductive portion 222 may be used to transmit a specific signal, for example, may be arranged with a constant voltage potential. In this way, at least one of the first conductive portion 221 and the second conductive portion 222 can also reduce capacitance formed between the charge present in the substrate 10 and the active layer 30 and reduce the risk of electric leakage of the thin film transistor, thereby improving the operational reliability of the thin film transistor.

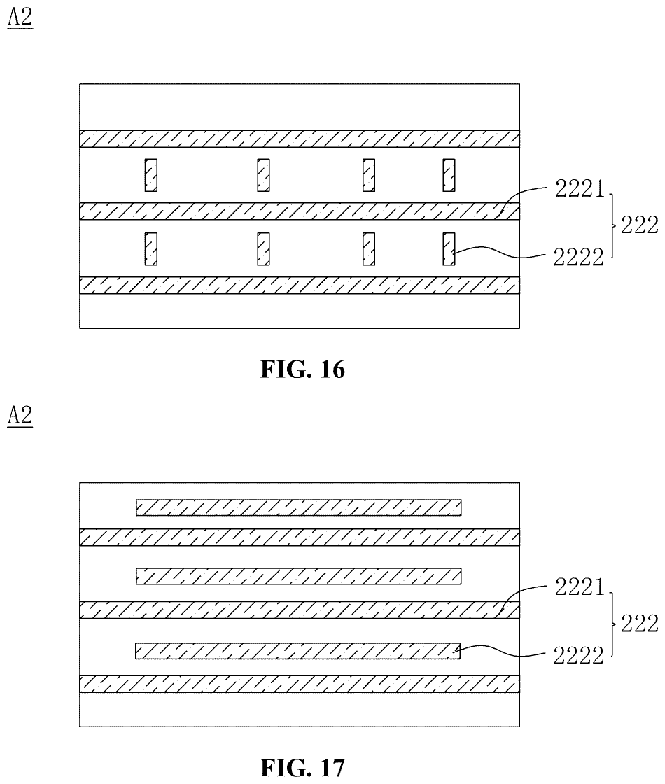

In some embodiments, referring to FIG. 15 and FIG. 16, the first conductive portion 221 includes a first portion 2211, the second conductive portion 222 includes a second portion 2221 and a third portion 2222. The first portion 2211 transmits the same type of signals as the second portion 2221, and the third portion 2222 is insulated from the first portion 2211 and the second portion 2221.

Both the first portion 2211 and the second portion 2221 are conductors that are inherently present in the first conductor layer, while the third portion 2222 is a new conductor added within the first conductor layer in order to improve the bonding yield. The first portion 2211 and the second portion 2221 transmit the same type of signals, while the third portion 2222 may be used to transmit specific signals, or the third portion 2222 may not transmit signals, i.e., the third portion 2222 may or may not be arranged with a potential. Further, when the third portion 2222 is used to transmit a specific signal, the type of the specific signal may be the same as or different from that of the first portion 2211.

In the embodiments of the present application, by adding the third portion 2222 in the first conductor layer at the second zone A2, it is possible to increase the area of the orthogonal projection of the second conductive portion 222 on the substrate, such that the area of the orthogonal projection of the second conductive portion 222 on the substrate is greater than the area of the orthogonal projection of the first conductive portion 221 on the substrate, thereby increasing the bonding yield and quality.

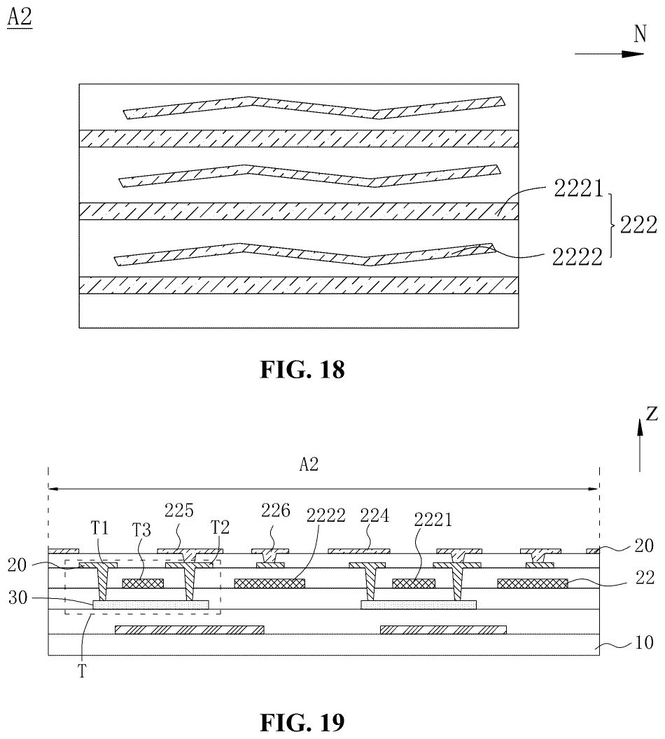

In some embodiments, referring to FIG. 17, an extension direction of the third portion 2222 is parallel to an extension direction of the second portion 2221. The “extension direction of the third portion 2222” here refers to the direction corresponding to the overall extension trend of the third portion 2222. The third portion 2222 may be in the shape of a straight line. Or referring to FIG. 18, the third portion 2222 may be in the shape of a folded line or a curved line, etc., and the extension direction of the third portion 2222 is direction N shown in the figure. The extension direction of the second portion 2221 can be arranged in the same way.

The second portion 2221 is a conductor inherently present in the second conductive portion 222. The third portion 2222 is an additional conductor to increase the area of the orthogonal projection of the second conductive portion 222. Both the second portion 2221 and the third portion 2222 are integrated within the second zone A2. Further, in an embodiment of the present application, in order to improve rationality of the layout of the second portion 2221 and the third portion 2222 and reduce the risk of cross-interference therebetween, the extension direction of the third portion 2222 is arranged to be parallel to the extension direction of the second portion 2221, which can reduce layout difficulty of the conductors of the first conductor layer 22 within the second zone A2, as well as reduce the risk of interference between the second portion 2221 and the third portion 2222.

It is to be noted that the length of the third portion 2222 may be greater than, less than or equal to the length of the second portion 2221, which is not limited in the embodiments of the present application. The third portion 2222 may be connected integrally with other conductors outside of the second zone A2, or the third portion 2222 may be spaced apart from other conductors outside of the second zone A2. The second portion 2221 can be arranged in the same way. In FIG. 16, the second portion 2221 is connected integrally with the other conductors outside the second zone A2, and the third portion 2222 is spaced apart from the other conductors outside the second zone A2.

In some embodiments, referring to FIG. 19, the third portion 2222 transmits a constant voltage signal, and an orthogonal projection of the third portion 2222 on the substrate overlaps an orthogonal projection of at least part of other conductors in the conductor structure on the substrate.

A voltage signal is present within the third portion 2222, and it is a constant voltage. Further, the orthogonal projection of the third portion 2222 on the substrate 10 overlaps the orthogonal projection of at least part of the other conductors in the conductor structure on the substrate 10. Herein, “the other conductors in the conductor structure 21” refers to the conductors in other conductor layers 20 of the plurality of conductor layers 20 other than the first conductor layer 22. In other words, the orthogonal projection of the third portion 2222 on the substrate 10 overlaps the orthogonal projection of at least part of the structure of the conductors in the other conductor layers 20 other than the first conductor layer 22 on the substrate 10. In this way, with the constant voltage signal transmitted in the third portion 2222, a signal shielding effect can be achieved on those conductors, and the reliability of signal transmission within the array base plate can be improved.

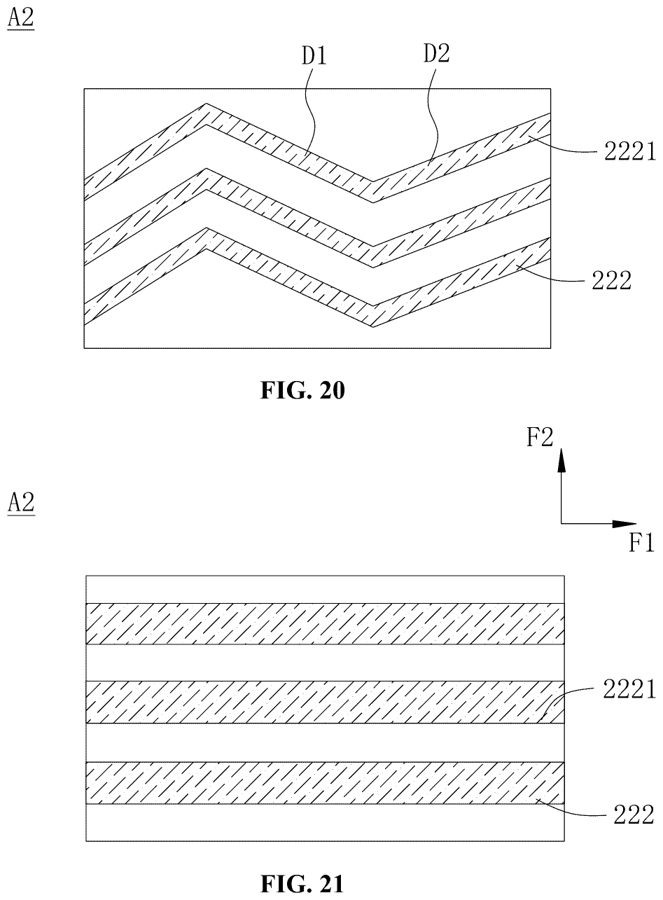

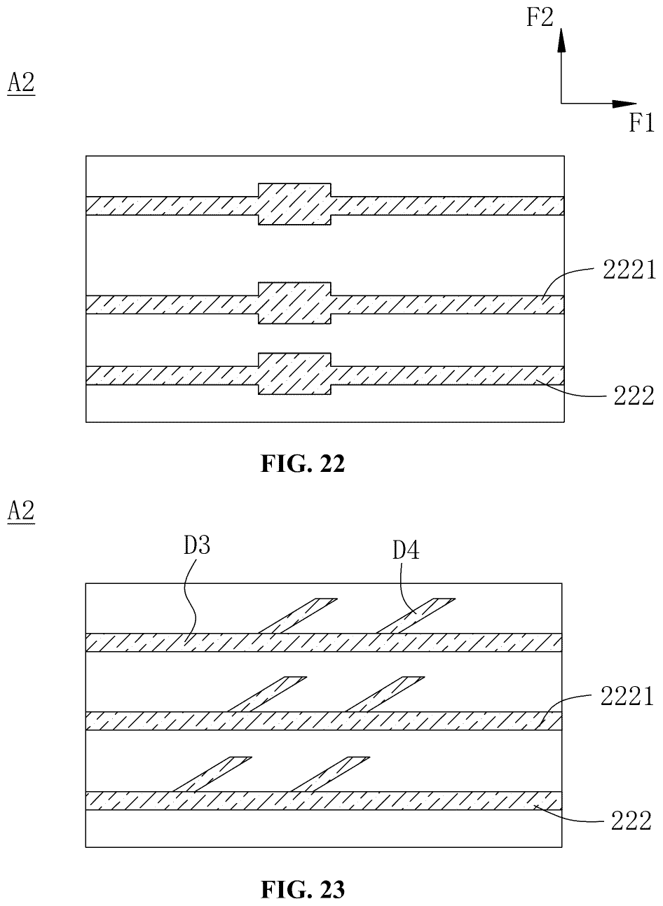

In some embodiments, referring to FIG. 15, FIG. 20, and FIG. 21, the first conductive portion 221 includes a first portion 2211, and the second conductive portion 222 includes a second portion 2221. The first portion 2211 transmits the same type of signals as the second portion 2221. The length of the second portion 2221 is greater than the length of the first portion 2211; and/or, the width of at least part of the structure of the second portion 2221 is greater than the width of the first portion 2211. In FIG. 15, FIG. 21, and FIG. 22, the length direction is illustrated as F1 and the width direction is illustrated as F2.

Both the first portion 2211 and the second portion 2221 are conductors that are inherently present in the first conductor layer. In order to increase the area of the orthogonal projection of the second conductive portion 222, a new conductor may be added, or the dimensional parameter of the second portion 2221 may also be adjusted. Specifically, the area of the orthogonal projection of the second conductive portion 222 can be increased by adjusting the length of the second portion 2221 or adjusting the width of the second portion 2221 at some or all of the positions. FIG. 21 illustrates a case in which the width of the second portion 2221 is increased at all positions, while FIG. 22 illustrates a case in which the width of the second portion 2221 is increased at only some positions.

It is to be noted that, solution of adjusting the length of the second portion 2221 may be realized in various forms. For example, if the second portion 2221 is in the shape of a straight line, it is possible to increase its size in the extension direction while maintaining the shape of the straight line, so as to increase the length of the second portion 2221. Or it may also be transformed into other shapes, so as to increase the length of the second portion 2221.

In addition, in an embodiment of the present application, the first conductor layer may or may not be provided with a third portion 2222, which is not limited in the embodiments of the present application. FIG. 17 and FIG. 18 illustrate cases where the first conductor layer is not provided with the third portion 2222.

In summary, in the embodiments of the present application, on the basis of the original conductor layout, the size such as the length and the width of a part of the conductors at the second zone A2 can be increased, so that there is a difference in size of the first conductor layer 22 between the first zone A1 and the second zone A2, so as to increase the area of the orthogonal projection of the second conductive portion 222, and to improve the bonding yield and quality.

It is to be noted that in the embodiments of the present application, only one of the length and the width of the conductors in the different regions may be adjusted, or both the length and the width may be adjusted at the same time. Further, only the length or the width of the conductors in one film layer may be adjusted at different regions, or the length or the width of the conductors in multiple film layers may also be adjusted at different regions.

In some embodiments, referring to FIG. 20 and FIG. 23, the second portion 2221 includes a first sub-section D1 and a second sub-section D2 arranged alternately, and the first sub-section D1 intersects the second sub-section D2 in an extension direction; and/or the second portion 2221 includes a main section structure D3 and a branch section structure D4 extending from the middle of the main section structure D3, and the main section structure D3 intersect the branch section structure D4 in an extension direction.

In order to increase the length of the second portion 2221, the extension manner of the second portion 2221 may be adjusted. Specifically, the second portion 2221 may be arranged to include a first sub-section D1 and a second sub-section D2 arranged alternately, and the extension directions of the first sub-section D1 and the second sub-section D2 are not parallel. The first sub-section D1 and the second sub-section D2 may be in the shape of a straight line, or may also be in the shape of a curved line, etc. The number of the first sub-sections D1 and the second sub-sections D2 may be one, or may also be more than one. FIG. 20 illustrates the case where both the first sub-section D1 and the second sub-section D2 are in the shape of a straight line and the number of both is plurality. As can be seen in conjunction with the accompanying drawings, in this design, the second portion 2221 is in the shape of a folded line overall and the length of the second portion 2221 can be greater than that of the first portion 2211 which is in the shape of a straight line.

Alternatively, in some other embodiments, the second portion 2221 may also include a main section structure D3 and a branch section structure D4. The main section structure D3 is the constituent basis of the second portion 2221, which is the same or similar as the first portion 2211 in extension manner and length.

The branch section structure D4 is a branch extending from the middle of the main section structure D3. Herein “the middle of the main section structure D3” does not refer to the right center position of the main section structure D3, but refers to any position of the main section structure D3 other than two ends. The number of branch section structures D4 may be one or may also be a plurality. When the number of branch section structures D4 is a plurality, at least part of the branch section structures D4 may be located on the same side or on different sides of the main section structure D3. The at least part of the branch section structures D4 may extend from the same position or different positions of the main section structure D3. FIG. 23 illustrates the case where a plurality of branch section structures D4 extend from different positions of the main section structure D3 and located on the same side of the main section structure D3.

It should be noted that when the second portion 2221 includes the main section structure D3 and the branch section structure D4, the length of the second portion 2221 is the sum of the length of the main section structure D3 and the length of all the branch section structures D4. This design can also increase the length of the second portion 2221. In this way, the area of the orthogonal projection of the second conductive portion 222 on substrate 10 is larger than the area of the orthogonal projection of the first conductive portion 221 on substrate 10, so as to improve the bonding yield and quality.

Furthermore, for the plurality of conductor layers, the structure of only one of the conductor layers may be adjusted, or the structure of multiple conductor layers may be adjusted. For example, it is possible to arrange the conductors of one of the conductor layers located in the second zone A2 to include the first sub-section D1 and the second sub-section D2, and the conductors of other conductor layers located in the second zone A2 to include the main section structure D3 and the branch section structure D4.

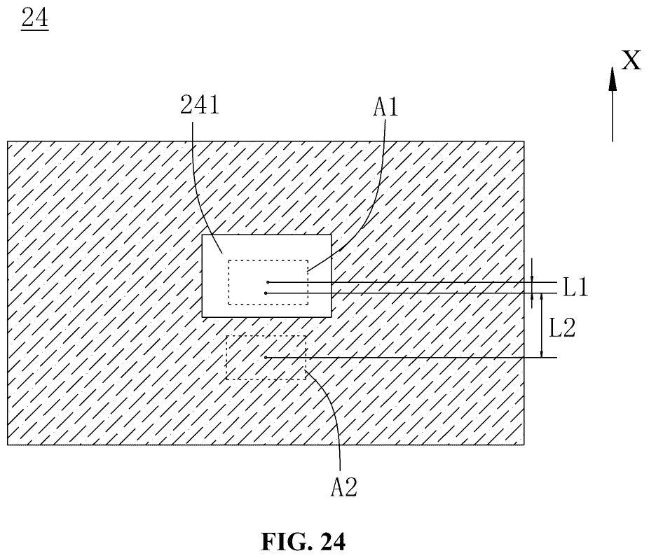

In some embodiments, referring to FIG. 24, the plurality of conductor layers includes a third conductor layer 24 which includes a hollow structure 241. The hollow structure 241 covers the first zone A1.

The third conductor layer 24 is one of the plurality of conductor layers and may be in a variety of positional forms. For example, the third conductor layer 24 may be located on the side of the active layer facing the substrate, or the third conductor layer 24 may be located on the side of the active layer facing away from the substrate.

The third conductor layer 24 includes a hollow structure 241 which may be in a variety of forms. For example, the third conductor layer 24 may be a plane structure, and the hollow structure 241 is a hole in that plane structure. Or the third conductor layer 24 may include a plurality of trace structures, and the hollow structure 241 is a regional structure formed by the avoidance of the plurality of trace structures. FIG. 20 illustrates the case where the third conductor layer 24 is a plane structure.

In an embodiment of the present application, the hollow structure 241 covers the first zone A1, i.e., the third conductor layer 24 is not provided with a conductor at the first zone A1. The orthogonal projection of the third conductor layer 24 on the substrate is located outside the orthogonal projection of the first zone A1 on the substrate, and the orthogonal projection of the third conductor layer 24 on the substrate overlap the orthogonal projection of the second zone A2 on the substrate. Likewise, this contributes to enable the area of the orthogonal projection of the conductor structure in the second zone A2 to be greater than the area of the orthogonal projection of the conductor structure in the first zone A1, so as to improve the bonding yield and quality.

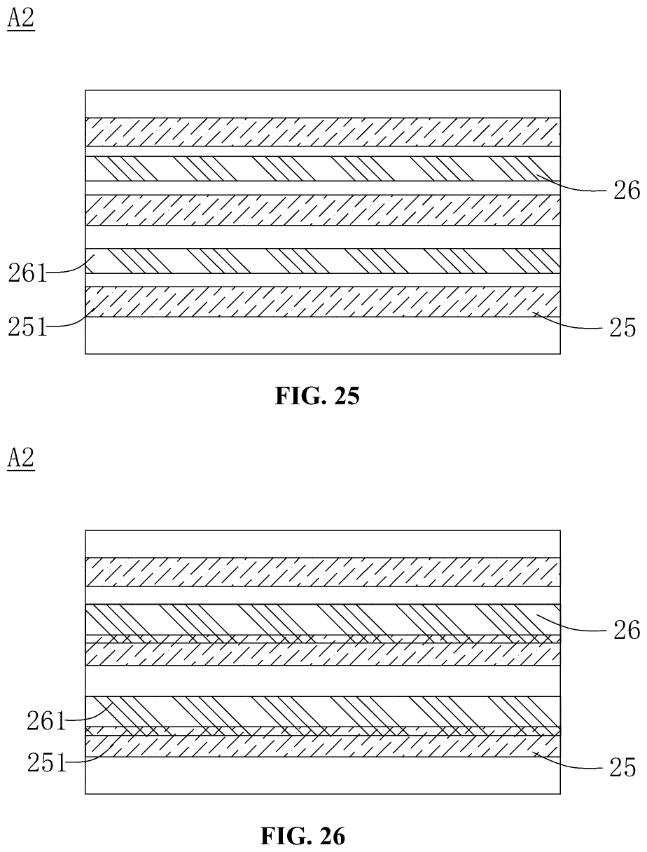

In some embodiments, referring to FIG. 25 and FIG. 26, the array base plate includes a fourth conductor layer 25 and a fifth conductor layer 26 that are stacked and insulated. The fourth conductor layer 25 includes a third conductive portion 251 located within the second zone A2. The fifth conductor layer 26 includes a fourth conductive portion 261 located within the second zone A2. The fourth conductor layer 25 and the fifth conductor layer 26 have a second projection area Y2 at the second zone A2. An area of an orthogonal projection of the third conductive portion 251 on the substrate is Z1, and an area of an orthogonal projection of the fourth conductive portion 261 on the substrate is Z2. When the orthogonal projection of the third conductive portion 251 on the substrate overlaps the orthogonal projection of the fourth conductive portion 261 on the substrate and an overlapping area therebetween is a first overlapping area J1, Y2=Z1+Z2−J1. Or when the orthogonal projection of the third conductive portion 251 on the substrate 10 does not overlap the orthogonal projection of the fourth conductive portion 261 on the substrate, Y2=Z1+Z2.

The fourth conductor layer 25 and the fifth conductor layer 26 are two of the plurality of conductor layers. The fourth conductor layer 25 and the fifth conductor layer 26 may be two adjacent conductor layers, or another conductor layer may exist between the fourth conductor layer 25 and the fifth conductor layer 26, which is not limited in embodiments of the present application.

The third conductive portion 251 is a conductor in the fourth conductor layer 25 located within the second zone A2. The fourth conductive portion 261 is a conductor in the fifth conductor layer 26 located within the second zone A2. The fourth conductor layer 25 and the fifth conductor layer 26 have a first projection area Z1 at the first zone A1 and a second projection area Z2 at the second zone A2. The orthogonal projections of the third conductive portion 251 and the fourth conductive portion 261 on the substrate may or may not overlap, and for the two cases, there will be a difference in calculating the second projection area Y2.

Specifically, when the orthogonal projection of the third conductive portion 251 on the substrate and the orthogonal projection of the fourth conductive portion 261 on the substrate do not overlap, the second projection area Y2 is equal to the sum of the area Z1 of the orthogonal projection of the third conductive portion 251 and the area Z2 of the orthogonal projection of the fourth conductive portion 261, i.e., Y2=Z1+Z2.

When the orthogonal projection of the third conductive portion 251 on the substrate and the orthogonal projection of the fourth conductive portion 261 on the substrate overlap, the second projection area Y2 is equal to the sum of the area Z1 of the orthogonal projection of the third conductive portion 251 and the area Z2 of the orthogonal projection of the fourth conductive portion 261 minus a first overlapping area J1 between the third conductive portion 251 and the fourth conductive portion 261, i.e., Y2=Z1+Z2−J1. In other words, during calculation of the areas of the orthogonal projections of the third conductive portion 251 and the fourth conductive portion 261, the area of the orthogonal projection at the overlapping region is not double-counted.

It is to be noted that the area of the orthogonal projection of the conductor structure 21 can be calculated in the same manner. Further, when the plurality of conductor layers 20 includes only the fourth conductor layer 25 and the fifth conductor layer 26, the area of the orthogonal projection of the conductor structure 21 at the second zone A2 is the second projection area Y2. When the plurality of conductor layers 20 includes other conductor layers 20 in addition to the fourth conductor layer 25 and the fifth conductor layer 26, the area of the orthogonal projection of the conductor structure 21 at the second zone A2 can be calculated in the same manner as that provided in the embodiments of the present application, i.e., the area of the orthogonal projection at the overlapping region is not double-counted.

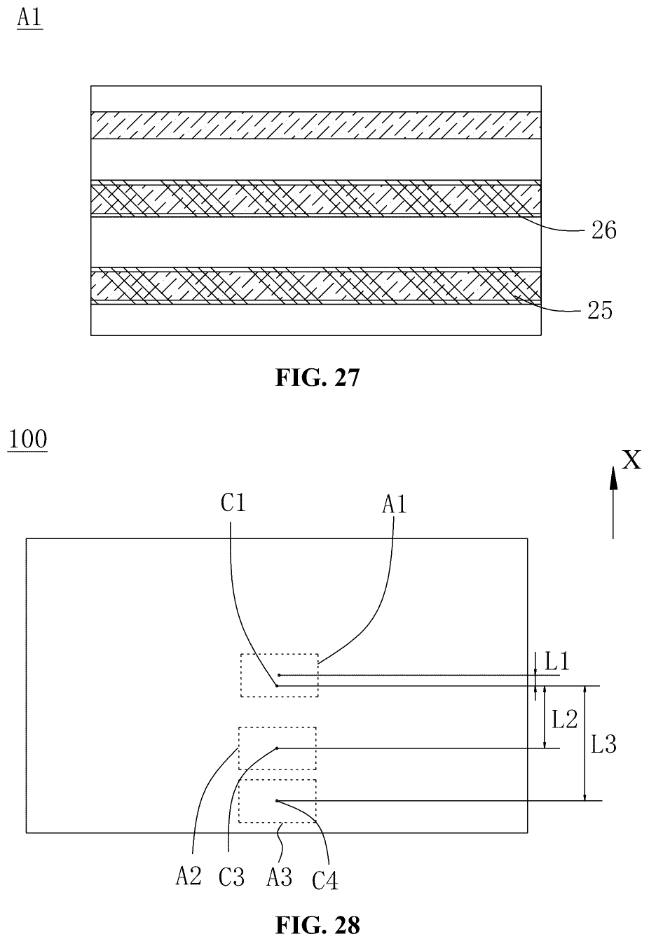

In some embodiments, referring to FIG. 26 and FIG. 27, an area of an orthogonal projection of a part of structure of the fourth conductor layer 25 within the second zone A2 on the substrate is greater than an area of an orthogonal projection of a part of structure of the fourth conductor layer 25 within the first zone A1 on the substrate; and/or an area of an orthogonal projection of a part of structure of the fifth conductor layer 26 within the second zone A2 on the substrate is greater than an area of an orthogonal projection of a part of structure of the fifth conductor layer 26 within the first zone A1 on the substrate; and/or an overlapping area between the orthogonal projection of a part of structure of the fourth conductor layer 25 within the first zone A1 on the substrate and the orthogonal projection of a part of structure of the fifth conductor layer 26 within the first zone A1 on the substrate is greater than an overlapping area between the orthogonal projection of a part of structure of the fourth conductor layer 25 within the second zone A2 on the substrate and the orthogonal projection of a part of structure of the fifth conductor layer 26 within the second zone A2 on the substrate.

When the plurality of conductor layers 20 includes at least the fourth conductor layer 25 and the fifth conductor layer 26, the size of the conductors in at least one of the fourth conductor layer 25 and the fifth conductor layer 26 at different regions or relative positions of the conductors in the fourth conductor layer 25 and the fifth conductor layer 26 may be adjusted in order to enable the area of the orthogonal projection of the conductor structure within the second zone A2 on the substrate to be greater than the area of the orthogonal projection of the conductor structure within the first zone A1 on the substrate, which is highly flexible. Different cases will next be described respectively in the embodiments of the present application.

In one case, the size of the conductors in the fourth conductor layer 25 can be adjusted. Specifically, the area of the orthogonal projection of the part of the structure of the fourth conductor layer 25 within the second zone A2 on the substrate may be arranged to be greater than the area of the orthogonal projection of the part of the structure of the fourth conductor layer 25 within the first zone A1 on the substrate, so that the area of the orthogonal projection of the conductor structure within the second zone A2 on the substrate is greater than the area of the orthogonal projection of the conductor structure within the first zone A1 on the substrate.

In another case, the size of the conductors in the fifth conductor layer 26 may also be adjusted. Specifically, the area of the orthogonal projection of the part of the structure of the fifth conductor layer 26 within the second zone A2 on the substrate may be arranged to be greater than the area of the orthogonal projection of the part of the structure of the fifth conductor layer 26 within the first zone A1 on the substrate, such that the area of the orthogonal projection of the conductor structure within the second zone A2 on the substrate is greater than the area of the orthogonal projection of the conductor structure within the first zone A1 on the substrate.

In other cases, the overlapping state between the fourth conductor layer 25 and the fifth conductor layer 26 may be adjusted. Specifically, the overlapping area between the fourth conductor layer 25 and the fifth conductor layer 26 at the second zone A2 may be reduced by changing the conductor layout manner of at least one of the fourth conductor layer 25 and the fifth conductor layer 26. In this case, even without changing the size of the conductors in the fourth conductor layer 25 and the fifth conductor layer 26, it also facilitates to increase the area of the orthogonal projection of the conductor structure within the second zone A2, such that the area of the orthogonal projection of the conductor structure within the second zone A2 on the substrate is greater than the area of the orthogonal projection of the conductor structure within the first zone A1 on the substrate. FIG. 26 and FIG. 27 illustrate cases where a difference in the areas of the orthogonal projections of the fourth conductor layer 25 and the fifth conductor layer 26 exists by adjusting overlapping relationship between the two film layers without changing the size of the conductors therein.

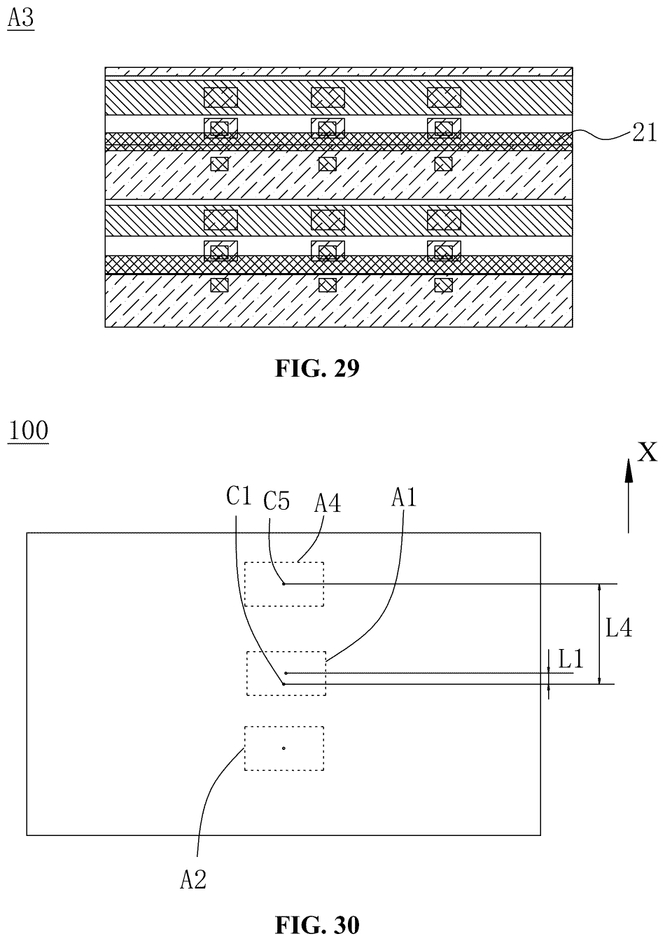

In some embodiments, referring to FIG. 4, FIG. 28, and FIG. 29, the array base plate 100 further includes a third zone A3. An area of an orthogonal projection of the third zone A3 on the substrate 10 is equal to the area of the orthogonal projection of the second zone A2 on the substrate 10. In the first direction X, the third zone A3 is located on a side of the second zone A2 away from the center C1 of the array base plate 100. An area of an orthogonal projection of the conductor structure 21 in the third zone A3 on the substrate is greater than the area of the orthogonal projection of the conductor structure 21 in the second zone A2 on the substrate.

The third zone A3 is in a different position from the first zone A1 and the second zone A2. The third zone A3 and the second zone A2 are located on the same side of the center C1 of the array base plate 100 along the first direction X. The areas of the orthogonal projections of the first zone A1, the second zone A2, and the third zone A3 on the substrate 10 are the same. The third zone A3 may be in a variety of shapes. For example, the orthogonal projection of the third zone A3 on the substrate 10 may be in a regular shape such as a circle or a square, or it may be in an irregular shape. FIG. 28 illustrates the case where the orthogonal projections of the first zone A1, the second zone A2, and the third zone A3 are all square.

In the first direction X, the third zone A3 is located on the side of the second zone A2 away from the center C1 of the array base plate 100. That is, the distance L3 between the center of the third zone A3 and the center C1 of the array base plate 100 in the first direction X is greater than the distance L2 between the center C3 of the second zone A2 and the center C1 of the array base plate 100 in the first direction X. The center C4 of the third zone A3 may coincide with the center C1 of the array base plate 100 in the first direction X. In this case, the distance between the center C4 of the third zone A3 and the center C1 of the array base plate 100 in the first direction X is the connecting distance therebetween. Or the center C4 of the third zone A3 may not coincide with the center C1 of the array base plate 100 in the first direction X. In this case, the distance between the center C4 of the third zone A3 and the center C1 of the array base plate 100 in the first direction X is less than the connecting distance therebetween.

Combined with the foregoing, it can be seen that for the line spot bonding and the plane spot bonding, the bonding temperature at the edge region tends to be lower than the bonding temperature at the center region. In the array base plate 100, the second zone A2 is closer to the center of the array base plate 100 in the first direction X relative to the third zone A3, so that the bonding temperature at the third zone A3 tends to be lower than the bonding temperature at the second zone A2 during the bonding process.

In view of this, in the embodiment of the present application, the structural layout and the like of the conductor structure 21 in the second zone A2 and the third zone A3 is adjusted, so that the area of the orthogonal projection of the conductor structure 21 within the third zone A3 on the substrate is greater than the area of the orthogonal projection of the conductor structure 21 within the second zone A2 on the substrate. The area of the orthogonal projection of the conductor structure 21 in a particular region tends to be positively correlated with the ability of the array base plate 100 to absorb external heat in that region. In other words, the third zone A3 of the array base plate 100 has a stronger heat absorption ability compared to the second zone A2. On this basis, even though the bonding temperature at the third zone A3 is lower than the bonding temperature at the second zone A2, since the third zone A3 has a stronger heat absorption ability, the difference between the actual temperatures of the array base plate 100 at the second zone A2 and the third zone A3 can be reduced, so that the actual temperatures of the second zone A2 and the third zone A3 can be the same or similar, and the bonding yield and quality can thus be improved.

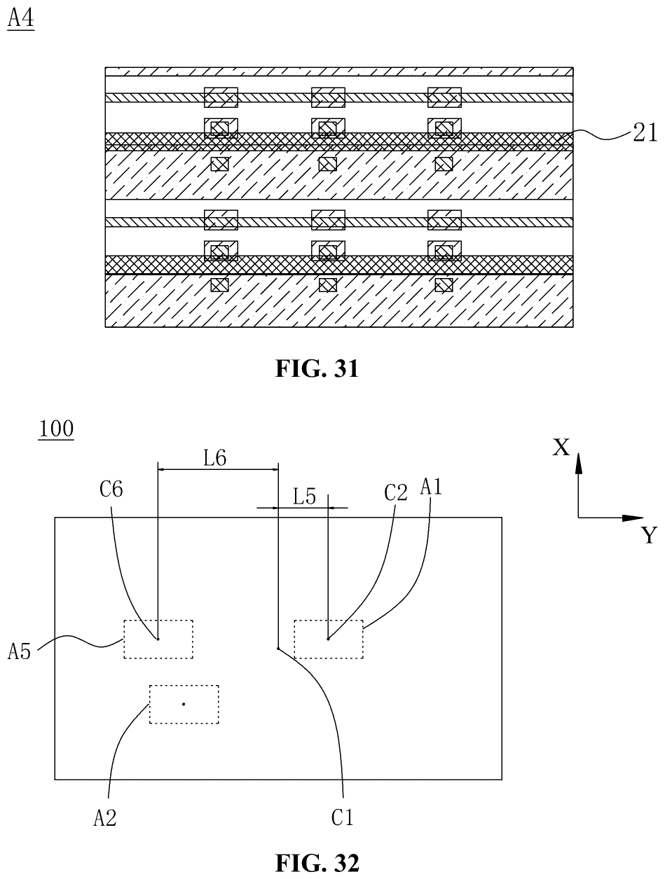

In some embodiments, referring to FIG. 3, FIG. 30, and FIG. 31, the array base plate 100 further includes a fourth zone A4. The fourth zone A4 and the second zone A2 are separately arranged on respective sides of the first zone A1 and the center C1 of the array base plate 100 in the first direction X. An area of an orthogonal projection of the fourth zone A4 on the substrate 10 is equal to the area of the orthogonal projection of the first zone A1 on the substrate 10. An area of an orthogonal projection of the conductor structure 21 within the fourth zone A4 on the substrate 10 is greater than the area of the orthogonal projection of the conductor structure 21 within the first zone A1 on the substrate 10.

The fourth zone A4 and the second zone A2 are located on different sides of the center C1 of the array base plate 100 along the first direction X. The areas of the orthogonal projections of the first zone A1, the second zone A2, and the fourth zone A4 on the substrate 10 are the same. The fourth zone A4 may be in a variety of shapes. For example, the orthogonal projection of the fourth zone A4 on the substrate 10 may be in a regular shape such as a circle or a square, or it may be in an irregular shape. FIG. 30 illustrates the case where the orthogonal projection of the fourth zone A4 on the substrate 10 is square.

Combined with the accompanying drawings, it can be seen that similar to the second zone A2, the distance L4 between the center C5 of the fourth zone A4 and the center C1 of the array base plate 100 in the first direction X is greater than the distance L1 between the center C2 of the first zone A1 and the center C1 of the array base plate 100 in the first direction X. On this basis, in an embodiment of the present application, the conductor structure 21 within the fourth zone A4 is further adjusted, so that the area of the orthogonal projection of the conductor structure 21 within the fourth zone A4 on the substrate 10 is greater than the area of the orthogonal projection of the conductor structure 21 within the first zone A1 on the substrate 10, thereby improving the bonding yield and quality.

It is to be noted that the size relationship of the areas of the orthogonal projections of the conductor structure 21 within the second zone A2 and the fourth zone A4 can be determined with reference to the distances of the center C3 of the second zone A2 and the center C5 of the fourth zone A4 with respect to the center C1 of the array base plate 100 in the first direction X, which is not limited in the embodiments of the present application.

In some embodiments, referring to FIG. 32, the array base plate 100 includes a fifth zone A5. An area of an orthogonal projection of the fifth zone A5 on the substrate is equal to the area of the orthogonal projection of the first zone A1 on the substrate. Along the second direction Y, the distance between the center C1 of the array base plate 100 and the fifth zone A5 is greater than the distance between the center C1 of the array base plate 100 and the first zone A1. The first direction intersects the second direction. An area of an orthogonal projection of the conductor structure within the fifth zone A5 on the substrate is greater than the area of the orthogonal projection of the conductor structure within the first zone A1 on the substrate.

The first direction X and the second direction Y are parallel to the plane where the substrate 10 is located and intersect with each other. Optionally, the first direction X is perpendicular to the second direction Y. Further, in the case where the array base plate 100 is projected in a square shape in the thickness direction Z, for example, the first direction X and the second direction Y may be parallel to two adjacent sides of the square shape respectively.

The fifth zone A5 is in a different position from the first zone A1. The areas of the orthogonal projections of the first zone A1 and the fifth zone A5 on the substrate 10 are the same. The fifth zone A5 may be in a variety of shapes. For example, the orthogonal projection of the fifth zone A5 on the substrate 10 may be in a regular shape such as a circle or a square, or it may be in an irregular shape. FIG. 32 illustrates the case where the orthogonal projection of the fifth zone A5 on the substrate 10 is square.

Along the second direction Y, the distance between the center C1 of the array base plate 100 and the fifth zone A5 is greater than the distance between the center C1 of the array base plate 100 and the first zone A1. That is, the distance L6 between the center C6 of the fifth zone A5 and the center C1 of the array base plate 100 in the second direction Y is greater than the distance L5 between the center C2 of the first zone A1 and the center C1 of the array base plate 100 in the second direction Y. The center C6 of the fifth zone A5 may coincide with the center C1 of the array base plate 100 in the second direction Y. In this case, the distance between the center C6 of the fifth zone A5 and the center C1 the array base plate 100 in the second direction Y is the connecting distance therebetween. Alternatively, the center C6 of the fifth zone A5 may not coincide with the center C1 of the array base plate 100 in the second direction Y. In this case, the distance between the center C6 of the fifth zone A5 and the center C1 the array base plate 100 in the second direction Y is less than the connecting distance therebetween. The distance between the center C2 of the first zone A1 and the center C1 of the array base plate 100 in the second direction Y can be arranged in the same manner.

In combination with the foregoing, it can be seen that for the plane spot bonding, compared to the center region, poor bonding may occur at each of the surrounding edge regions due to a lower bonding temperature. In view of this, in an embodiment of the present application, not only the area of the orthogonal projection of the conductor structure at the second zone A2 is increased, but also the area of the orthogonal projection of the conductor structure at the fifth zone A5 is increased, so that the conductor dimensions can be compensated at different locations around the center C1 of the array base plate 100, thereby improving the bonding yield and quality at different locations around the center C1.

It is to be noted that for the plane spot bonding, the bonding temperatures corresponding to the different regions depend on the distances relative to the center C1 of the array base plate 100 in the first direction X and the second direction Y, i.e., the bonding temperature in a particular region depend on the distance between the center C1 of the array base plate 100 and that region in the first direction X and the distance between the center C1 of the array base plate 100 and that region in the second direction Y. Exemplarily, if the distance between the fifth zone A5 and the center C1 of the array base plate 100 in the second direction Y is greater than the distance between the second zone A2 and the center C1 of the array base plate 100 in the first direction X, then optionally, the area of orthogonal projection of the conductor structure within the fifth zone A5 on the substrate is greater than the area of orthogonal projection of the conductor structure within the second zone A2 on the substrate.

In some embodiments, the conductor structure 21 includes a metallic material.

In the embodiments of the present application, the metallic material is capable of absorbing more external light and heat as compared to a light-transmissive material. Thus, by arranging the conductor structure 21 to include the metallic material, more external heat is absorbed with the conductor structure 21 during the bonding process, so as to increase the actual temperature of the array base plate 100. The actual temperature of the array base plate 100 at different regions can be adjusted by adjusting the size of different orthogonal projections of the conductor structure 21 at different regions, thereby improving the bonding yield and quality.

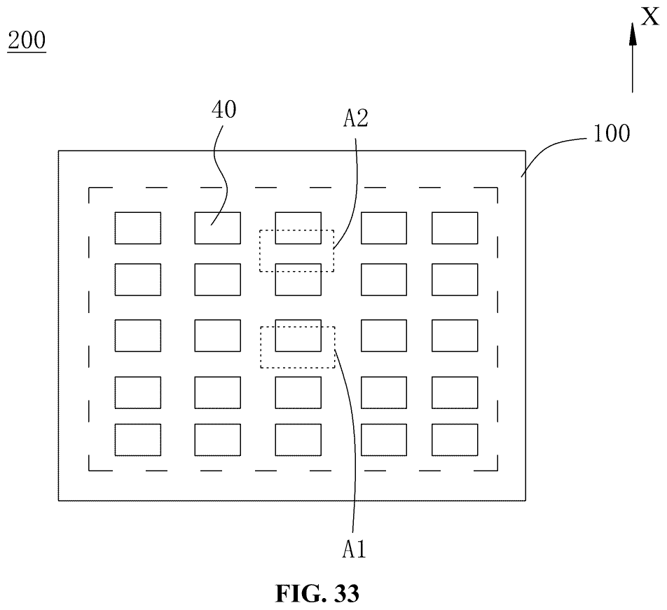

In a second aspect, referring to FIG. 7 and FIG. 33, embodiments of the present application provides a display panel 200 that includes the array base plate 100 and a plurality of light emitting elements 40 in any of the aforementioned embodiments. A part of the light emitting elements 40 are bonded to the first zone A1 of the array base plate 100 and a part of the light emitting elements 40 are bonded to the second zone A2 of the array base plate 100.

The light emitting elements 40 may be in various forms, as long as the light emitting elements 40 are bonded to the array base plate 100. Optionally, the light emitting element 40 includes, but is not limited to, a micro light emitting diode (Micro LED) as well as a sub-millimeter light emitting diode (Mini LED).

It should be noted that the first zone A1 and the second zone A2 are regions on the array base plate 100 for bonding and fixing the light emitting elements 40. The display panel 200 may be in various forms. For example, the display panel 200 is provided with the light emitting element 40 at each region, i.e., the display panel 200 does not include a border region that is not used for light emitting display. On this basis, the first zone A1 and the second zone A2 can be correspondingly arranged at any location of the array base plate 100, as long as the distance between the center of the first zone A1 and the center of the array base plate 100 in the first direction X is less than the distance between the center of the second zone A2 and the center of the array base plate 100 in the first direction X.

In some other embodiments, the display panel 200 includes a display region and a border region located at the periphery of the display region. The light emitting elements 40 are provided only at the display region, but do not exist within the border region. On this basis, the first zone A1 and the second zone A2 need to be located within the display region of the display panel 200 correspondingly rather than within the border region.

In addition, the display panel 200 according to the embodiments of the present application can achieve the beneficial effects of the array base plate 100 in any of the foregoing embodiments, which can be understood referring to the foregoing description of the beneficial effects of the array base plate 100 and will not be repeated in the embodiments of the present application.

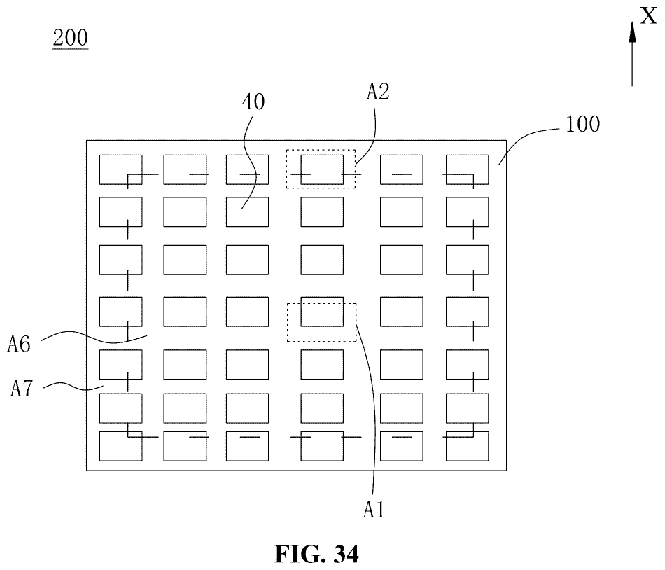

In some embodiments, referring to FIG. 34, the display panel 200 includes a sixth zone A6 and a seventh zone A7 arranged on at least one side of the sixth zone A6. A part of the light emitting elements 40 are arranged within the sixth zone A6 and a part of the light emitting elements 40 are arranged within the seventh zone A7. The array base plate 100 includes a pixel circuit (not shown in the figures). An orthogonal projection of the pixel circuit on the substrate is located within the sixth zone A6 but not within the seventh zone A7. The orthogonal projection of the first zone A1 on the substrate is located within an orthogonal projection of the sixth zone A6 on the substrate. The orthogonal projection of the second zone A2 on the substrate overlaps an orthogonal projection of the seventh zone A7 on the substrate 10.

The display panel 200 includes at least the sixth zone A6 and the seventh zone A7. Exemplarily, the sixth zone A6 may include the center region of the display panel 200, and the seventh zone A7 may include an edge region of the display panel 200. The seventh zone A7 is on at least one side of the sixth zone A6, i.e., the seventh zone A7 may be arranged on one side of the sixth zone A6 along a single direction, or the seventh zone A7 may be in a ring-like structure and arranged around the outer peripheral side of the sixth zone A6.

The pixel circuit is a circuit structure for controlling the light emitting element 40. An orthogonal projection of the pixel circuit on the substrate 10 is located within the sixth zone A6 and outside the seventh zone A7, i.e., the pixel circuit is arranged within the sixth zone A6 and not within the seventh zone A7. For the light emitting elements 40, a part of the light emitting elements 40 are arranged within the sixth zone A6 and a part of the light emitting elements 40 are arranged within the seventh zone A7, i.e., the light emitting elements 40 are correspondingly arranged at various positions of the display panel 200, so as to enable light emitting display to be realized at various positions of the display panel 200. The light emitting elements 40 within the seventh zone A7 and the sixth zone A6 are both driven and controlled by the pixel circuit within the sixth zone A6.

In an embodiment of the present application, since the light emitting elements 40 are distributed both within the sixth zone A6 and the seventh zone A7, it is necessary to perform the bonding for both the light emitting elements 40 within the sixth zone A6 and the light emitting elements 40 within the seventh zone A7 during the bonding process. Relative to the sixth zone A6, the seventh zone A7 is further away from the center of the array base plate 100, so the bonding temperature at the seventh zone A7 tends to be lower than the bonding temperature at the sixth zone A6.

In view of this, in an embodiment of the present application, the conductor structure in the second zone A2 that is overlapped with the seventh zone A7 is adjusted, so that the conductor structure 21 in the seventh zone A7 can have a larger orthogonal projection area, thereby reducing the actual temperature difference between the sixth zone A6 and the seventh zone A7, and improving the bonding yield and quality at the seventh zone A7.

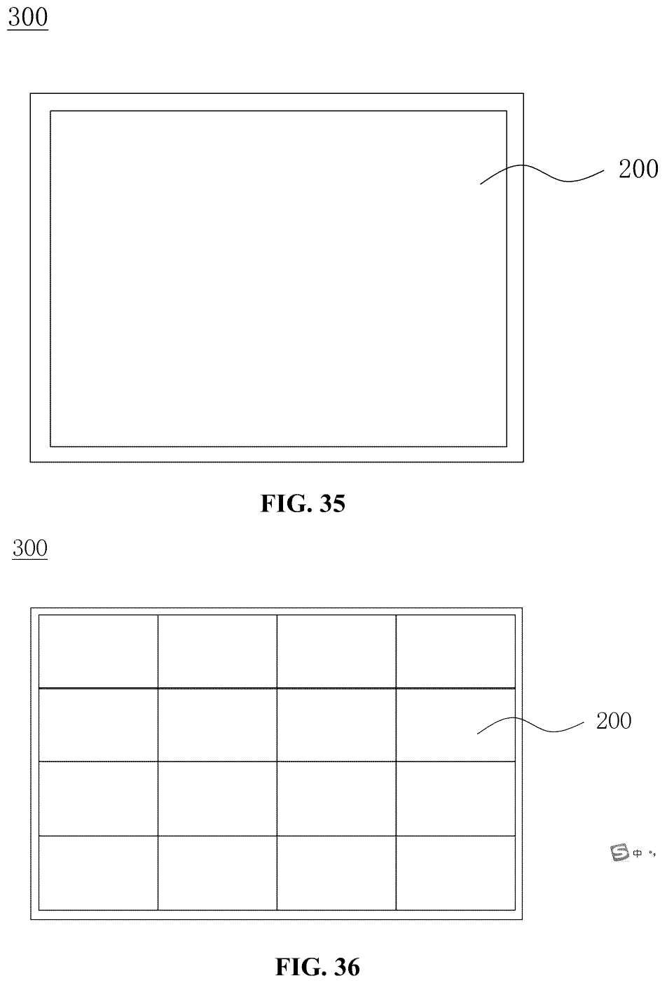

In a third aspect, referring to FIG. 35, an embodiment of the present application provides a display apparatus 300 that includes the display panel 200 in any of the preceding embodiments.

It is noted that the display apparatus 300 may include only one display panel 200 or a plurality of display panels 200, which is not limited in the embodiments of the present application. The display apparatus 300 according to the embodiments of the present application can achieve the beneficial effects of the display panel 200 in any of the foregoing embodiments, which can be understood referring to the foregoing description of the beneficial effects of the display panel 200 and the array base plate 100 and will not be repeated in the embodiments of the present application.

In some embodiments, referring to FIG. 36, the display apparatus 300 includes a plurality of display panels 200 provided in collocation.

In an embodiment of the present application, the display apparatus 300 may include a plurality of display panels 200. For each of the plurality of display panels 200, fixing connection between the array base plate 100 and the light emitting elements 40 may be realized by means of laser bonding. Further, for an individual display panel 200 in the display apparatus 300, the area of the orthogonal projection of the conductor structure 21 at different regions may be adjusted, so as to improve the bonding yield of the display panel 200, and to improve yield rate and reliability of the display apparatus 300.

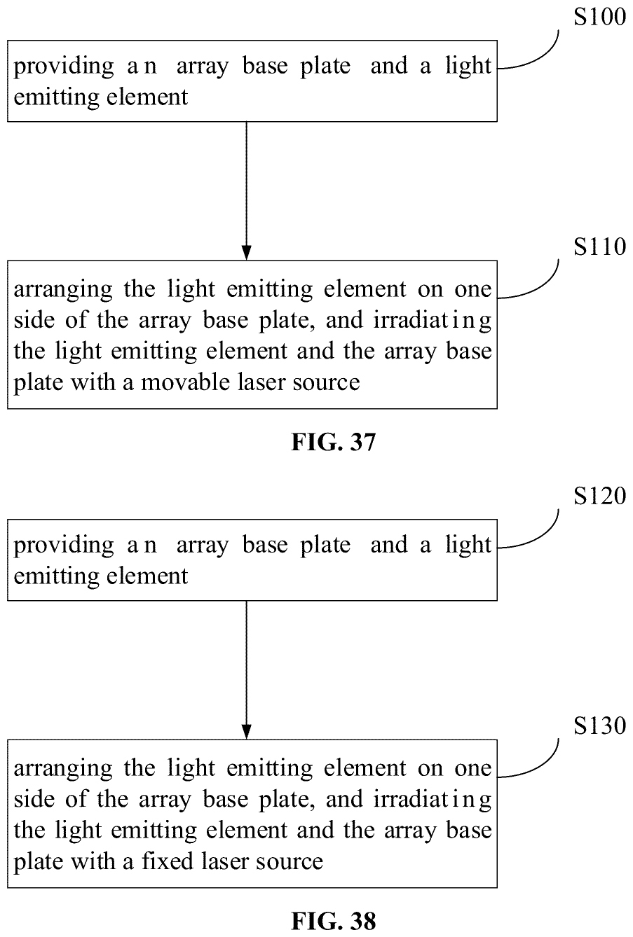

In a fourth aspect, referring to FIG. 37, an embodiment of the present application provides a method of manufacturing a display panel which includes S100 and S110.

At S100, an array base plate and a light emitting element are provided.

In step S100, the array base plate is an array base plate in any of the preceding embodiments. Specifically, referring to FIG. 1 to FIG. 7, the array base plate includes a substrate and a plurality of conductor layers 20 stacked on one side of the substrate. The plurality of conductor layers 20 are provided with a conductor structure 21 therein. The array base plate 100 includes a first zone A1 and a second zone A2. An area of an orthogonal projection of the first zone A1 on the substrate 10 is equal to an area of an orthogonal projection of the second zone A2 on the substrate 10. Along a first direction X, a distance between a center C1 of the array base plate 100 and the second zone A2 is greater than a distance between the center C1 of the array base plate 100 and the first zone A1. The first direction X is parallel to a plane where the substrate 10 is located. An area of an orthogonal projection of the conductor structure 21 within the second zone A2 on the substrate 10 is greater than an area of an orthogonal projection of the conductor structure 21 within the first zone A1 on the substrate 10.

At S110, the light emitting element is arranged on one side of the array base plate, and the light emitting element and the array base plate are irradiated with a movable laser source.

In step S110, the movable laser source may be a line spot laser, which moves along a third direction M and enable the light emitting element 40 to be bonded and fixed to the array base plate 100. The first direction X intersects the third direction M, and both are parallel to the plane where the substrate 10 is located. During the bonding process, the bonding temperature at the edge of the line spot tends to be higher than the bonding temperature at the center of the line spot, while the center of the line spot tends to coincide with or be close to the center C1 of the array base plate 100 in the third direction M. Therefore, when the line spot is moved to irradiate the first zone A1, and when it is moved to irradiate the second zone A2, the bonding temperature at the second zone A2 tends to be lower than the bonding temperature at the first zone A1.

In view of this, in an embodiment of the present application, the structural layout and the like of the conductor structure 21 in the first zone A1 and the second zone A2 is adjusted, such that the area of the orthogonal projection of the conductor structure 21 within the second zone A2 on the substrate 10 is greater than the area of the orthogonal projection of the conductor structure 21 within the first zone A1 on the substrate 10. In this way, the second zone A2 of the array base plate 100 has a stronger heat absorption ability compared to the first zone A1. Thus, the difference between the actual temperatures of the array base plate 100 at the first zone A1 and the second zone A2 can be reduced, so that the actual temperatures of the first zone A1 and the second zone A2 can be the same or similar, and the bonding yield and quality can thus be improved.

In a fifth aspect, referring to FIG. 38, an embodiment of the present application provides a method of manufacturing a display panel which includes S120 and S130.

At S120, an array base plate and a light emitting element are provided.

In step S120, the array base plate is an array base plate in any of the preceding embodiments. Specifically, referring to FIG. 3 to FIG. 7, the array base plate includes a substrate 10 and a plurality of conductor layers 20 stacked on one side of the substrate 10. The plurality of conductor layers 20 are provided with a conductor structure 21 therein. The array base plate includes a first zone A1 and a second zone A2. An area of an orthogonal projection of the first zone A1 on the substrate 10 is equal to an area of an orthogonal projection of the second zone A2 on the substrate 10. Along a first direction X, a distance between a center of the array base plate and the second zone A2 is greater than a distance between the center of the array base plate and the first zone A1. The first direction X is parallel to the plane where the substrate 10 is located. An area of an orthogonal projection of the conductor structure 21 within the second zone A2 on the substrate 10 is greater than an area of an orthogonal projection of the conductor structure 21 within the first zone A1 on the substrate 10.

At S130, the light emitting element is arranged on one side of the array base plate, and the light emitting element and the array base plate are irradiated with a fixed laser source.

In step S130, the fixed laser source may be a plane spot laser, which is focused on the center of the array base plate and enable the light emitting element 40 to be bonded and fixed with the array base plate. In the bonding process, the bonding temperature at the edge of the plane spot tends to be higher than the bonding temperature at the center of the plane spot, while the plane spot laser is focused on the center of the array base plate, which results in the further away from the center of the array base plate, the lower the bonding temperature, i.e., the bonding temperature at the second zone A2 tends to be lower than the bonding temperature at the first zone A1.

In view of this, in an embodiment of the present application, the structural layout and the like of the conductor structure 21 in the first zone A1 and the second zone A2 is adjusted, such that the area of the orthogonal projection of the conductor structure 21 within the second zone A2 on the substrate 10 is greater than the area of the orthogonal projection of the conductor structure 21 within the first zone A1 on the substrate 10. In this way, the second zone A2 of the array base plate has a stronger heat absorption ability compared to the first zone A1. Thus, the difference between the actual temperatures of the array base plate at the first zone A1 and the second zone A2 can be reduced, so that the actual temperatures of the first zone A1 and the second zone A2 can be the same or similar, and the bonding yield and quality can thus be improved.

Although the embodiments disclosed in the present application are as described above, the contents described are only embodiments adopted for the purpose of facilitating the understanding of the present application, and are not intended to limit the present invention. Any person skilled in the art of the present application may, without departing from the spirit and scope of the disclosure of the present application, make any modifications and changes in the form and details of the embodiments, but the scope of protection of the present application shall still be subject to the scope defined in the appended claims.

The above description are only specific embodiments of the present application. It is clearly understood by those skilled in the art that, for the convenience and brevity of the description, corresponding process in the foregoing method embodiments may be referred to obtain the substitution of other connection manners and the like as described above, which will not be repeated herein. It should be understood that the scope of protection of the present application is not limited thereto, and any person skilled in the art may readily conceive various equivalent modifications or substitutions within the scope of the technology disclosed herein, all of which shall be covered by the scope of protection of the present application.

What is claimed is:

1. An array base plate comprising a substrate and a plurality of conductor layers stacked on one side of the substrate, the plurality of conductor layers being provided with a conductor structure therein,
wherein the array base plate includes a first zone and a second zone, an area of an orthogonal projection of the first zone on the substrate is equal to an area of an orthogonal projection of the second zone on the substrate, and along a first direction, a distance between a center of the array base plate and the second zone is greater than a distance between the center of the array base plate and the first zone, the first direction being parallel to a plane where the substrate is located, and
wherein an area of an orthogonal projection of the conductor structure within the second zone on the substrate is greater than an area of an orthogonal projection of the conductor structure within the first zone on the substrate.

2. The array base plate of claim 1, wherein the plurality of conductor layers includes a first conductor layer, the first conductor layer includes a first conductive portion located within the first zone and a second conductive portion located within the second zone, and an area of an orthogonal projection of the second conductive portion on the substrate is greater than an area of an orthogonal projection of the first conductive portion on the substrate.

3. The array base plate of claim 2, wherein the array base plate includes an active layer, and the first conductor layer is located on a side of the active layer facing away from the substrate, the plurality of the conductor layers further include a second conductor layer, and the second conductor layer is located between the first conductor layer and the active layer.

4. The array base plate of claim 3, wherein the first conductive portion and the second conductive portion both transmit a power signal.

5. The array base plate of claim 2, wherein the first conductor layer is a plane structure.

6. The array base plate of claim 5, wherein the first conductor layer is provided with hollow portions, and the hollow portions are at least partially located within the first zone, and wherein
a number of the hollow portions within the first zone is greater than a number of the hollow portions within the second zone; and/or
an area of an orthogonal projection of the hollow portion within the first zone on the substrate is greater than an area of an orthogonal projection of the hollow portion within the second zone on the substrate.

7. The array base plate of claim 5, wherein the first conductor layer includes a first power supply structure, and the first power supply structure is to provide a first supply voltage.

8. The array base plate of claim 7, wherein the first conductor layer further includes a first pad, and the first pad is insulated from the first power supply structure.

9. The array base plate of claim 2, wherein the array base plate further includes an active layer, and the first conductor layer is located on a side of the active layer facing the substrate, and the orthogonal projection of the first conductive portion on the substrate and the orthogonal projection of the second conductive portion on the substrate both overlap an orthogonal projection of the active layer on the substrate.

10. The array base plate of claim 2, wherein the first conductive portion includes a first portion, the second conductive portion includes a second portion and a third portion, the first portion transmits a same type of signal as the second portion, and the third portion is insulated from the first portion and the second portion.

11. The array base plate of claim 10, wherein the third portion transmits a constant voltage signal, and an orthogonal projection of the third portion on the substrate overlaps an orthogonal projection of at least part of other conductors of the conductor structure on the substrate.

12. The array base plate of claim 2, wherein the first conductive portion includes a first portion, the second conductive portion includes a second portion, the first portion transmits a same type of signal as the second portion, and a length of the second portion is greater than a length of the first portion; and/or
a width of at least part of the structure of the second portion is greater than a width of the first portion.

13. The array base plate of claim 12, wherein the second portion includes a first sub-section and a second sub-section arranged alternately, and the first sub-section intersect the second sub-section in an extension direction; and/or
the second portion includes a main section structure and a branch section structure extending from a middle of the main section structure, and the main section structure intersect the branch section structure in an extension direction.

14. The array base plate of claim 1, wherein the plurality of conductor layers include a third conductor layer, the third conductor layer includes a hollow structure, and the hollow structure covers the first zone.

15. The array base plate of claim 1, wherein the array base plate includes a fourth conductor layer and a fifth conductor layer stacked and insulated, the fourth conductor layer includes a third conductive portion within the second zone, the fifth conductor layer includes a fourth conductive portion within the second zone, the fourth conductor layer and the fifth conductor layer have a second projection area Y2 at the second zone, an area of an orthogonal projection of the third conductive portion on the substrate is Z1, and an area of an orthogonal projection of the fourth conductive portion on the substrate is Z2;
wherein when the orthogonal projection of the third conductive portion on the substrate overlaps the orthogonal projection of the fourth conductive portion on the substrate and an overlapping area therebetween is a first overlapping area J1, Y2=Z1+Z2−J1, or
when the orthogonal projection of the third conductive portion on the substrate is located outside and does not overlap the orthogonal projection of the fourth conductive portion on the substrate, Y2=Z1+Z2.

16. The array base plate of claim 1, wherein the array base plate further includes a third zone, an area of an orthogonal projection of the third zone on the substrate is equal to the area of the orthogonal projection of the second zone on the substrate, and the third zone is located on a side of the second zone facing away from the center of the array base plate in the first direction, and
wherein an area of an orthogonal projection of the conductor structure within the third zone on the substrate is greater than an area of an orthogonal projection of the conductor structure within the second zone on the substrate.

17. The array base plate of claim 1, wherein the array base plate further includes a fifth zone, an area of an orthogonal projection of the fifth zone on the substrate is equal to the area of the orthogonal projection of the first zone on the substrate, and along a second direction, a distance between the center of the array base plate and the fifth zone is greater than a distance between the center of the array base plate and the first zone, the first direction intersecting the second direction, and
wherein an area of an orthogonal projection of the conductor structure within the fifth zone on the substrate is greater than the area of the orthogonal projection of the conductor structure within the first zone on the substrate.

18. A display panel comprising an array base plate and a plurality of light emitting elements,
wherein the array base plate includes a substrate and a plurality of conductor layers stacked on one side of the substrate, the plurality of conductor layers being provided with a conductor structure therein,
wherein the array base plate includes a first zone and a second zone, an area of an orthogonal projection of the first zone on the substrate is equal to an area of an orthogonal projection of the second zone on the substrate, and along a first direction, a distance between a center of the array base plate and the second zone is greater than a distance between the center of the array base plate and the first zone, the first direction being parallel to a plane where the substrate is located,
wherein an area of an orthogonal projection of the conductor structure within the second zone on the substrate is greater than an area of an orthogonal projection of the conductor structure within the first zone on the substrate, and
wherein a part of the light emitting elements are bonded to the first zone of the array base plate and a part of the light emitting elements are bonded to the second zone of the array base plate.

19. The display panel of claim 18, wherein the display panel includes a sixth zone and a seventh zone located on at least one side of the sixth zone, a part of the light emitting elements are arranged within the sixth zone, and a part of the light emitting elements are arranged within the seventh zone;
the array base plate includes a pixel circuit, and an orthogonal projection of the pixel circuit on the substrate is located within the sixth zone and outside the seventh zone; and
the orthogonal projection of the first zone on the substrate is located within an orthogonal projection of the sixth zone on the substrate, and the orthogonal projection of the second zone on the substrate overlaps an orthogonal projection of the seventh zone on the substrate.

20. A display apparatus comprising a display panel,
wherein the display panel includes an array base plate and a plurality of light emitting elements,
wherein the array base plate includes a substrate and a plurality of conductor layers stacked on one side of the substrate, the plurality of conductor layers being provided with a conductor structure therein,
wherein the array base plate includes a first zone and a second zone, an area of an orthogonal projection of the first zone on the substrate is equal to an area of an orthogonal projection of the second zone on the substrate, and along a first direction, a distance between a center of the array base plate and the second zone is greater than a distance between the center of the array base plate and the first zone, the first direction being parallel to a plane where the substrate is located,
wherein an area of an orthogonal projection of the conductor structure within the second zone on the substrate is greater than an area of an orthogonal projection of the conductor structure within the first zone on the substrate, and
wherein a part of the light emitting elements are bonded to the first zone of the array base plate and a part of the light emitting elements are bonded to the second zone of the array base plate.
